(19) United States
(12) Patent Application Publication
(10) Pub. No.: US 2023/0387056 A1
(43) Pub. Date: Nov. 30, 2023

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Yunsun Jang, Suwon-si (KR); Jungtae Sung, Suwon-si (KR); Moorym Choi, Suwon-si (KR)

(21) Appl. No.: 18/057,305

(22) Filed: Nov. 21, 2022

(30) Foreign Application Priority Data
May 25, 2022 (KR) 10-2022-0064172

(51) Int. Cl. H01L 23/00; H01L 25/065; H01L 25/18; H01L 23/535; H01L 27/11582; H01L 27/11573; H01L 25/00

(52) U.S. Cl. CPC H01L 24/08; H01L 25/0657; H01L 25/18; H01L 23/535; H01L 27/11582; H01L 27/11573; H01L 24/80; H01L 25/50; H01L 2224/08145; H01L 2224/80006; H01L 2224/80895; H01L 2224/80896; H01L 2924/1431; H01L 2924/14511

(57) ABSTRACT

Disclosed are three-dimensional semiconductor memory devices and electronic systems. The three-dimensional semiconductor memory device includes a first substrate that includes a cell array region and a contact region, a peripheral circuit structure on the first substrate, a cell array structure on the peripheral circuit structure wherein the cell array structure includes interlayer dielectric layers and gate electrodes that are alternately stacked, a dielectric layer on the stack structure, and a second substrate on the stack structure, a mold structure that penetrates the stack structure and includes a dielectric material, and a first through structure and a second through structure that penetrate the mold structure and are spaced apart from each other.

### CROSS-REFERENCE TO RELATED APPLICATION

This U.S. nonprovisional application claims priority under 35 U.S.C § 119 to Korean Patent Application No. 10-2022-0064172 filed on May 25, 2022 in the Korean Intellectual Property Office, the disclosure of which is hereby incorporated by reference in its entirety.

### BACKGROUND

The present inventive concepts relate to a three-dimensional semiconductor memory device and an electronic system including the same, and more particularly, to a nonvolatile three-dimensional semiconductor memory device including a vertical channel structure, a method of fabricating the same, and an electronic system including the same.

It may be necessary to have a semiconductor device capable of storing a large amount of data in an electronic system which requires data storage. Semiconductor devices have been highly integrated to meet high performance and low manufacturing cost which are desired by customers. Integration of typical two-dimensional or planar semiconductor devices is primarily determined by the area occupied by a unit memory cell, such that it is greatly influenced by the level of technology for forming fine patterns. However, the extremely expensive processing equipment needed to increase pattern fineness may set a practical limitation on increasing the integration of the two-dimensional or planar semiconductor devices. Therefore, there have been proposed three-dimensional semiconductor memory devices having three-dimensionally arranged memory cells.

### SUMMARY

Some embodiments of the present inventive concepts provide a three-dimensional semiconductor memory device whose integration is increased and a method of fabricating the same having the same.

Some embodiments of the present inventive concepts provide a three-dimensional semiconductor memory device whose reliability and electrical properties are improved and a method of fabricating the same having the same.

Some embodiments of the present inventive concepts provide an electronic system including the three-dimensional semiconductor memory device.

An object of the present inventive concepts is not limited to the mentioned above, and other objects which have not been mentioned above will be clearly understood to those skilled in the art from the following description.

According to some embodiments of the present inventive concepts, a three-dimensional semiconductor memory device may include a first substrate that includes a cell array region and a contact region, a peripheral circuit structure on the first substrate, a cell array structure on the peripheral circuit structure, wherein the cell array structure includes a stack structure including interlayer dielectric layers and gate electrodes that are alternately stacked on the peripheral circuit structure, a dielectric layer on the stack structure, and a second substrate on the stack structure, the gate electrodes including pad portions having a stepwise structure on the contact region, a vertical separation dam structure that penetrates the dielectric layer and at least a portion of the stack structure, wherein the vertical separation dam structure penetrates at least one of the pad portions, a mold structure that is adjacent to the vertical separation dam structure, the mold structure including a dielectric material, and through structures that penetrate the dielectric layer and the mold structure.

According to some embodiments of the present inventive concepts, a three-dimensional semiconductor memory device may include a first substrate that includes a cell array region and a contact region, a peripheral circuit structure on the first substrate, a cell array structure on the peripheral circuit structure, wherein the cell array structure includes interlayer dielectric layers and gate electrodes that are alternately stacked in a stack structure, a dielectric layer on the stack structure, and a second substrate on the stack structure, a mold structure that penetrates the stack structure and includes a dielectric material, and a first through structure and a second through structure that penetrate the mold structure and are spaced apart from each other.

According to some embodiments of the present inventive concepts, an electronic system may include a three-dimensional semiconductor memory device including a first substrate that includes a cell array region and a contact region, a peripheral circuit structure on the first substrate, a cell array structure on the peripheral circuit structure, a through contact that penetrates the cell array structure, a through contact that penetrates the cell array structure, and an input/output pad on the through contact, and a controller configured to electrically connect the input/output pad with the three-dimensional semiconductor memory device and to control the three-dimensional semiconductor memory device. The cell array structure may include interlayer dielectric layers and gate electrodes that are alternately stacked in a stack structure on the peripheral circuit structure, a second substrate on the stack structure, and a vertical separation dam structure and a capacitor that penetrate the stack structure. The gate electrodes may include pad portions having a stepwise structure on the contact region. The capacitor may include a first through structure and a second through structure that are spaced apart from each other. The vertical separation dam structure may be in one of the pad portions in a plan view. The first and second through structures may be surrounded by the vertical separation dam structure in the plan view.

### BRIEF DESCRIPTION OF THE DRAWINGS

FIG. 1 illustrates a simplified block diagram showing an electronic system that includes a three-dimensional semiconductor memory device according to some embodiments of the present inventive concepts.

FIG. 2 illustrates a simplified perspective view showing an electronic system that includes a three-dimensional semiconductor memory device according to some embodiments of the present inventive concepts.

FIGS. 3 and 4 illustrate cross-sectional views respectively taken along lines I-I′ and II-II′ of FIG. 2, showing a semiconductor package that includes a three-dimensional semiconductor memory device according to some embodiments of the present inventive concepts.

FIG. 5 illustrates a plan view showing a three-dimensional semiconductor memory device according to some embodiments of the present inventive concepts.

FIGS. 6A and 6B illustrate cross-sectional views respectively taken along lines I-I′ and II-II′ of FIG. 5, showing a three-dimensional semiconductor memory device according to some embodiments of the present inventive concepts.

FIG. 7A illustrates an enlarged view of section A depicted in FIG. 6A, partially showing a three-dimensional semiconductor memory device according to some embodiments of the present inventive concepts.

FIG. 7B illustrates an enlarged view of section B depicted in FIG. 6A, partially showing a three-dimensional semiconductor memory device according to some embodiments of the present inventive concepts.

FIG. 8 illustrates a cross-sectional view taken along line II-II′ of FIG. 5, showing a method of fabricating a three-dimensional semiconductor memory device according to some embodiments of the present inventive concepts.

FIGS. 9, 11, 13, and 15 illustrate plan views showing a method of fabricating a three-dimensional semiconductor memory device according to some embodiments of the present inventive concepts.

FIGS. 10, 12, 14A, 16A, and 17 illustrate cross-sectional views taken along line III-III′ of FIG. 9. 11, 13, or 15, showing a method of fabricating a three-dimensional semiconductor memory device according to some embodiments of the present inventive concepts.

FIGS. 14B and 16B illustrate cross-sectional views taken along line IV-IV′ of FIG. 13 or 15, showing a method of fabricating a three-dimensional semiconductor memory device according to some embodiments of the present inventive concepts.

### DETAILED DESCRIPTION

The following will now describe in detail a three-dimensional semiconductor memory device, a method of fabricating the same, and an electronic system including the same according to some embodiments of the present inventive concepts in conjunction with the accompanying drawings.

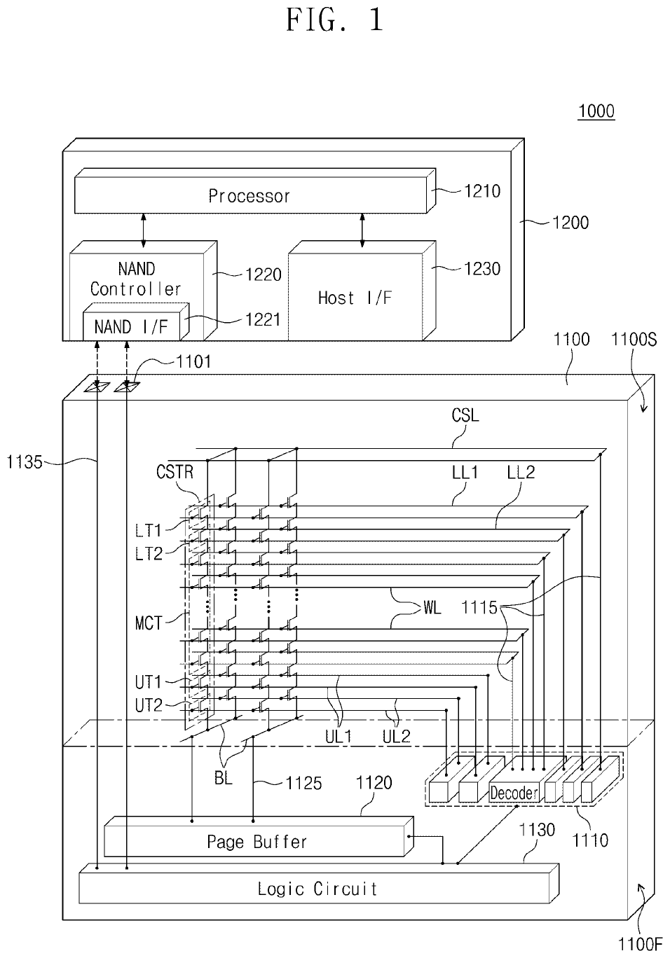

FIG. 1 illustrates a simplified block diagram showing an electronic system that includes a three-dimensional semiconductor memory device according to some embodiments of the present inventive concepts.

Referring to FIG. 1, an electronic system 1000 according to some embodiments of the present inventive concepts may include a three-dimensional semiconductor memory device 1100 and a controller 1200 electrically connected to the three-dimensional semiconductor memory device 1100. The electronic system 1000 may be a storage device that includes a single or a plurality of three-dimensional semiconductor memory devices 1100 or may be an electronic device that includes the storage device. For example, the electronic system 1000 may be a solid state drive (SSD) device, a universal serial bus (USB), a computing system, a medical apparatus, or a communication apparatus each of which includes a single or a plurality of three-dimensional semiconductor memory devices 1100.

The three-dimensional semiconductor memory device 1100 may be a nonvolatile memory device, such as a three-dimensional NAND Flash memory device which will be discussed below. The three-dimensional semiconductor memory device 1100 may include a first region 1100F and a second region 1100S on the first region 1100F. Different from that shown, the first region 1100F may be disposed on a side of the second region 1100S. The first region 1100F may be a peripheral circuit region that includes a decoder circuit 1110, a page buffer 1120, and a logic circuit 1130. The second region 1100S may be a memory cell region including bit lines BL, a common source line CSL, word lines WL, first lines LL1 and LL2, second lines UL1 and UL2, and memory cell strings CSTR between the bit lines BL and the common source line CSL.

On the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT between the first transistors LT1 and LT2 and the second transistors UT1 and UT2. The number of the first transistors LT1 and LT2 and of the second transistors UT1 and UT2 may be variously changed in accordance with embodiments. The memory cell strings CSTR may be positioned between the common source line CSL and the first region 1100F.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2, respectively. The word lines WL may be gate electrodes of the memory cell transistors MCT, and the second lines UL1 and UL2 may be gate electrodes of the second transistors UT1 and UT2.

For example, the first transistors LT1 and LT2 may include a first erasure control transistor LT1 and a ground selection transistor LT2 that are connected in series. For example, the second transistors UT1 and UT2 may include a string selection transistor UT1 and a second erasure control transistor UT2 that are connected in series. One or both of the first and second erasure control transistors LT1 and UT2 may be employed to perform an erase operation in which a gate induced drain leakage (GIDL) phenomenon is used to erase data stored in the memory cell transistors MCT.

The common source line CSL, the first lines LL1 and LL2, the word lines WL, and the second lines UL1 and UL2 may be electrically connected to the decoder circuit 1110 through first connection lines 1115 that extend from the first region 1100F toward the second region 1100S. The bit lines BL may be electrically connected to the page buffer 1120 through second connection lines 1125 that extend from the first region 1100F toward the second region 1100S.

On the first region 1100F, the decoder circuit 1110 and the page buffer 1120 may perform a control operation with respect to at least one selection memory cell transistor among the plurality of memory cell transistors MCT. The logic circuit 1130 may control the decoder circuit 1110 and the page buffer 1120. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first region 1100F toward the second region 1100S.

The controller 1200 may include a processor 1210, a NAND controller 1220, and a host interface 1230. According to some embodiments, the electronic system 1000 may include a plurality of three-dimensional semiconductor memory devices 1100, and in this case, the controller 1200 may control the plurality of three-dimensional semiconductor memory devices 1100.

The processor 1210 may control an overall operation of the electronic system 1000 that includes the controller 1200. The processor 1210 may operate based on certain firmware, and may control the NAND controller 1220 to access the three-dimensional semiconductor memory device 1100. The NAND controller 1220 may include a NAND interface 1221 that processes communication with the three-dimensional semiconductor memory device 1100. The NAND interface 1221 may be used to transfer therethrough a control command which is intended to control the three-dimensional semiconductor memory device 1100, data which is intended to be written on the memory cell transistors MCT of the three-dimensional semiconductor memory device 1100, and/or data which is intended to be read from the memory cell transistors MCT of the three-dimensional semiconductor memory device 1100. The host interface 1230 may provide the electronic system 1000 with communication with an external host. When a control command is received through the host interface 1230 from an external host, the three-dimensional semiconductor memory device 1100 may be controlled by the processor 1210 in response to the control command.

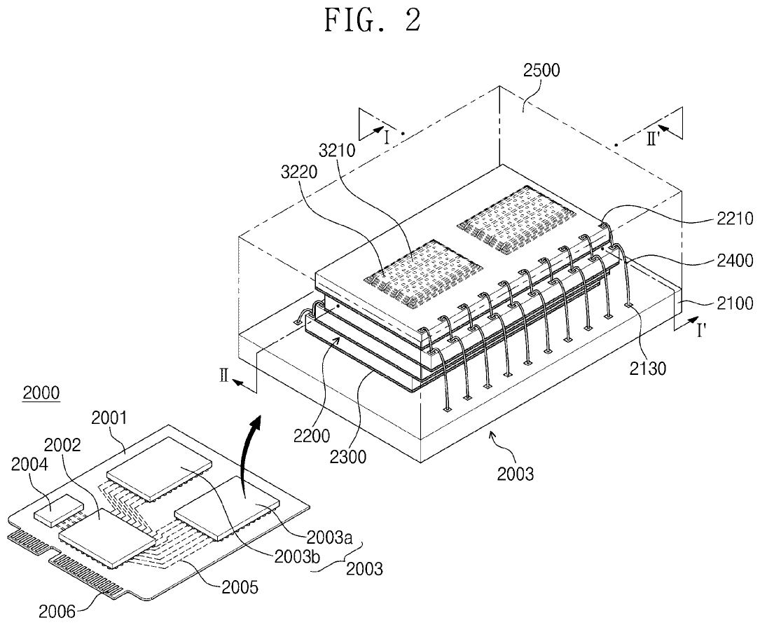

FIG. 2 illustrates a simplified perspective view showing an electronic system that includes a three-dimensional semiconductor memory device according to some embodiments of the present inventive concepts.

Referring to FIG. 2, an electronic system 2000 according to some embodiments of the present inventive concepts may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 through wiring patterns 2005 provided in the main board 2001. The main board 2001 may include a connector 2006 including a plurality of pins that are provided to have connection with an external host. The number and arrangement of the plurality of pins on the connector 2006 may be changed based on a communication interface between the electronic system 2000 and the external host. The electronic system 2000 may communicate with an external host through one or more interfaces, for example, universal serial bus (USB), peripheral component interconnect express (PIC-Express), serial advanced technology attachment (SATA), and M-PHY for universal flash storage (UFS). For example, the electronic system 2000 may operate with power supplied through the connector 2006 from an external host. The electronic system 2000 may further include a power management integrated circuit (PMIC) that distributes the power supplied from the external host to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but a DRAM controller for controlling the DRAM 2004.

The semiconductor package 2003 may include first and second semiconductor packages 2003a and 2003b that are spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesion layers 2300 correspondingly disposed on bottom surfaces of the semiconductor chips 2200, connection structures 2400 that electrically connect the semiconductor chips 2200 to the package substrate 2100, and a molding layer 2500 with which the semiconductor chips 2200 and the connection structures 2400 are covered or overlapped on the package substrate 2100.

The package substrate 2100 may be an integrated circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stack structures 3210 and memory channel structures 3220. Each of the semiconductor chips 2200 may include a three-dimensional semiconductor memory device which will be discussed below.

The connection structures 2400 may be, for example, bonding wires that electrically connect the input/output pads 2210 to the package upper pads 2130. Therefore, on each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, on each of the first and second semiconductor packages 2003a and 2003b, the semiconductor chips 2200 may be electrically connected to each other via through silicon vias instead of the connection structures 2400 or the boding wires.

Differently from that shown, the controller 2002 and the semiconductor chips 2200 may be included in a single package. The controller 2002 and the semiconductor chips 2200 may be mounted on a separate interposer substrate other than the main board 2001, and may be connected to each other through wiring lines provided in the interposer substrate.

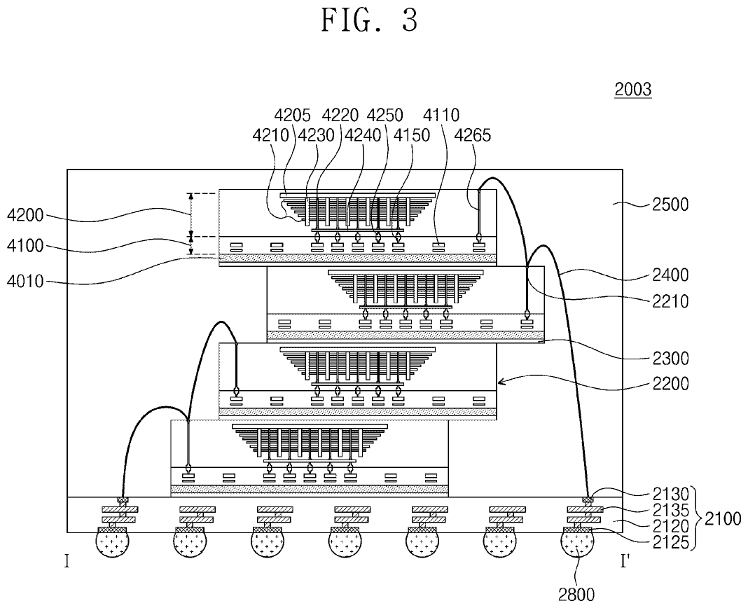

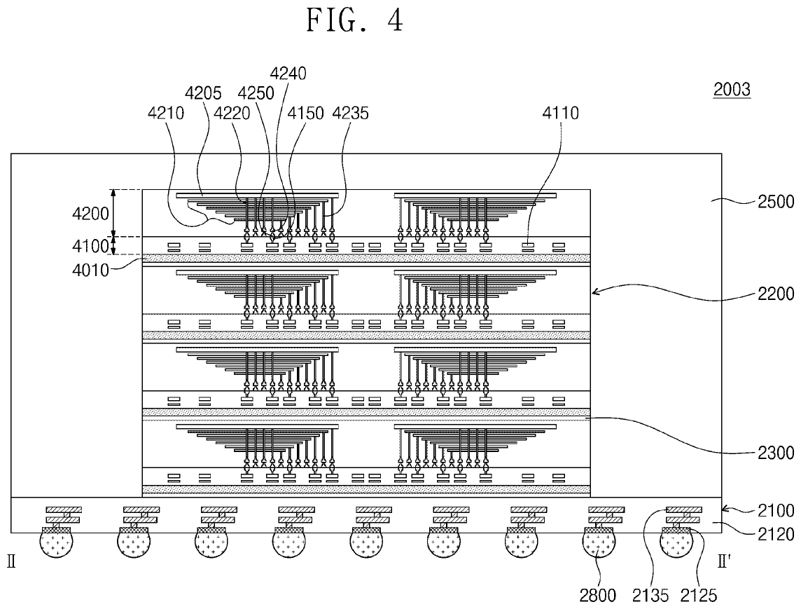

FIGS. 3 and 4 illustrate cross-sectional views respectively taken along lines I-I′ and II-II′ of FIG. 2, showing a semiconductor package that includes a three-dimensional semiconductor memory device according to some embodiments of the present inventive concepts.

Referring to FIGS. 3 and 4, a semiconductor package 2003 may include a package substrate 2100, a plurality of semiconductor chips 2200 on the package substrate 2100, and a molding layer 2500 that covers or overlaps the package substrate 2100 and the semiconductor chips 2200.

The package substrate 2100 may include a package substrate body 2120, upper pads 2130 disposed or exposed on a top surface of the package substrate body 2120, lower pads 2125 disposed or exposed on a bottom surface of the package substrate body 2120, and internal lines 2135 through which the upper pads 2130 and the lower pads 2125 are electrically connected within the package substrate body 2120. The upper pads 2130 may be electrically connected to connection structures 2400. The lower pads 2125 may be connected through conductive connectors 2800 to the wiring patterns 2005 in the main board 2001 of the electronic system 2000 depicted in FIG. 2.

Referring to FIGS. 2 and 3, the semiconductor chips 2200 may have sidewalls that are not aligned with each other and also have other sidewalls that are aligned with each other. The semiconductor chips 2200 may be electrically connected to each other thorough the connection structures 2400 shaped like bonding wires. The semiconductor chips 2200 may be configured substantially identical to each other.

Each of the semiconductor chips 2200 may include a semiconductor substrate 4010, a first structure 4100 on the semiconductor substrate 4010, and a second structure 4200 on the first structure 4100. The second structure 4200 and the first structure 4100 may be bonded to each other in a wafer bonding manner.

The first structure 4100 may include peripheral circuit lines 4110 and first bonding pads 4150. The second structure 4200 may include a common source line 4205, a gate stack structure 4210 between the common source line 4205 and the first structure 4100, memory channel structures 4220 and separation structures 4230 that penetrate the gate stack structure 4210, and second bonding pads 4250 electrically connected to the memory channel structures 4220 and word lines (see WL of FIG. 1) of the gate stack structure 4210. For example, the second bonding pads 4250 may be electrically connected to the memory channel structures 4220 and the word lines (see WL of FIG. 1) through bit lines 4240 electrically connected to the memory channel structures 4220 and gate connection lines 4235 electrically connected to the word lines (see WL of FIG. 1). The first bonding pads 4150 of the first structure 4100 may be bonded to and in contact with the second bonding pads 4250 of the second structure 4200. The first and second bonding pads 4150 and 4250 may have their contact portions including, for example, copper (Cu).

Each of the semiconductor chips 2200 may further include input/output pads 2210 and input/output connection lines 4265 below the input/output pads 2210. The input/output connection line 4265 may be electrically connected to one of the second boding pads 4250 and one of the peripheral circuit lines 4110.

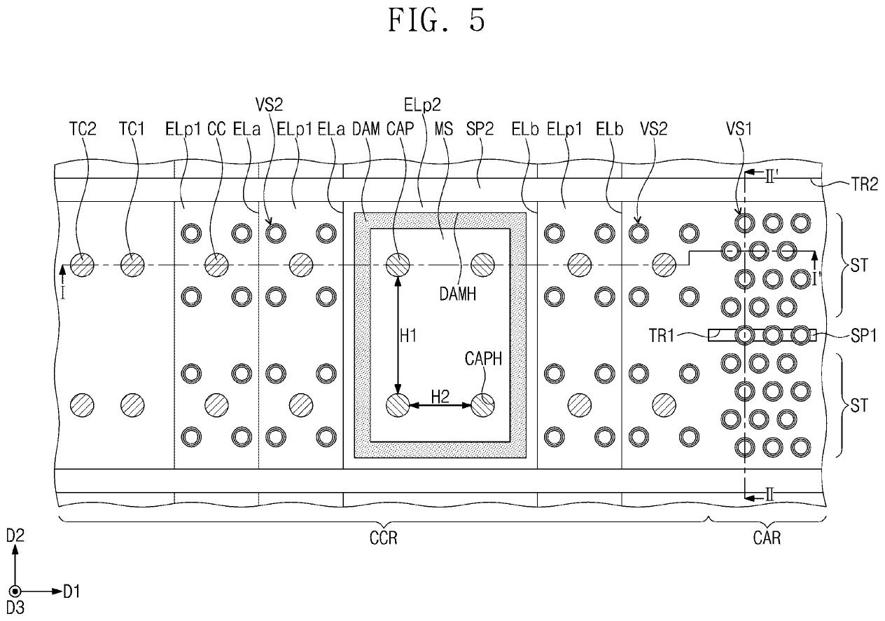

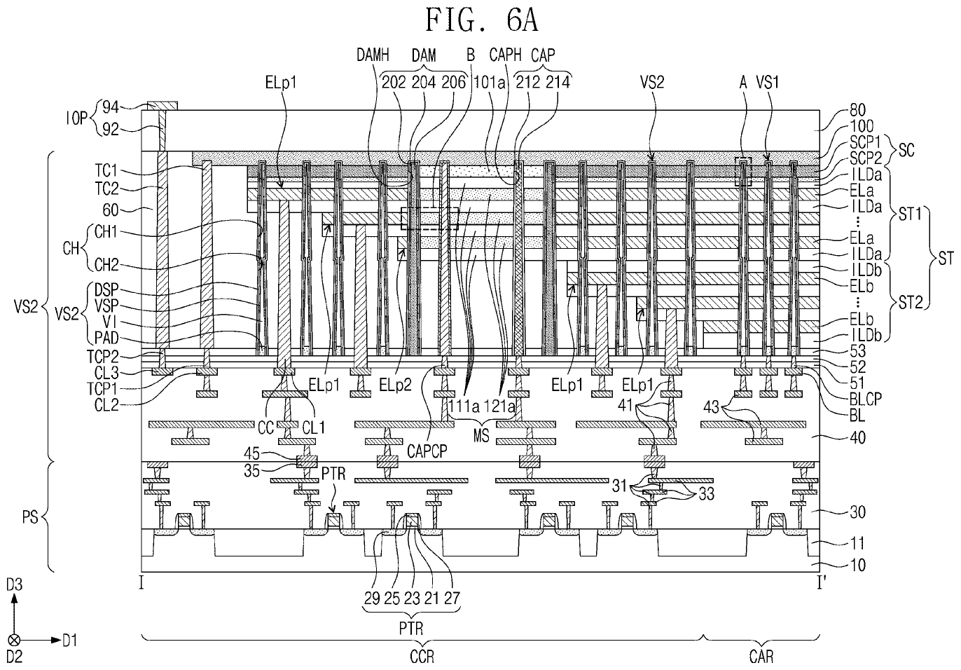

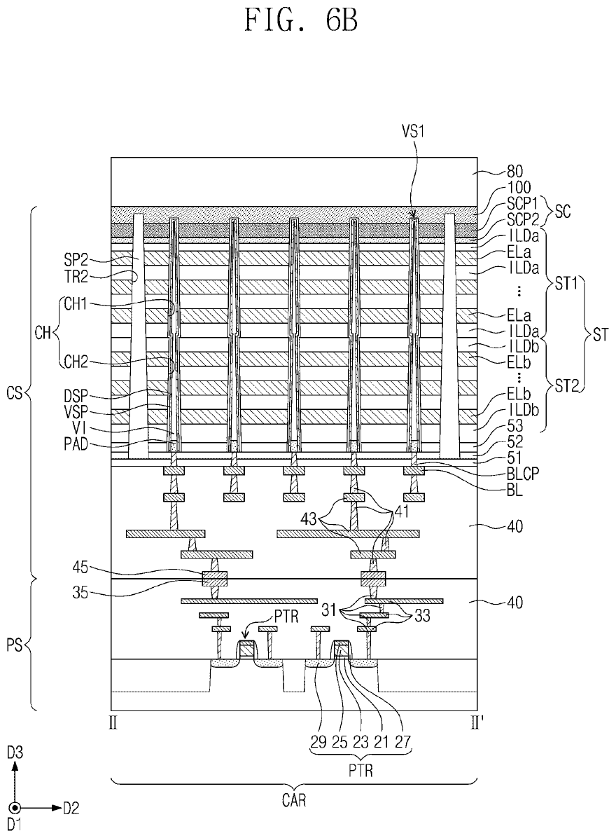

FIG. 5 illustrates a plan view showing a three-dimensional semiconductor memory device according to some embodiments of the present inventive concepts. FIGS. 6A and 6B illustrate cross-sectional views respectively taken along lines I-I′ and II-II′ of FIG. 5, showing a three-dimensional semiconductor memory device according to some embodiments of the present inventive concepts.

Referring to FIGS. 5, 6A, and 6B, a three-dimensional semiconductor memory device according to the present inventive concepts may include a first substrate 10, a peripheral circuit structure PS on the first substrate 10, and a cell array structure CS on the peripheral circuit structure PS. The first substrate 10, the peripheral circuit structure PS, and the cell array structure CS may respectively correspond to the semiconductor substrate 4010, the first structure 4100 on the semiconductor substrate 4010, and the second structure 4200 on the first structure 4100 of FIG. 3 or 4.

As the cell array structure CS is bonded onto the peripheral circuit structure PS, it may be possible to increase a cell capacity per unit area of the three-dimensional semiconductor memory device according to the present inventive concepts. In addition, as the peripheral circuit structure PS and the cell array structure CS are manufactured separately and then bonded to each other, peripheral transistors PTR may be prevented from being damaged due to various heat treatment processes, and accordingly, it may be possible to improve reliability and electrical properties of the three-dimensional semiconductor memory device according to the present inventive concepts.

The first substrate 10 may be, for example, a silicon substrate, a silicon-germanium substrate, a germanium substrate, or a monocrystalline epitaxial layer grown on a monocrystalline silicon substrate. The first substrate 10 may have a top surface parallel to a first direction D1 and a second direction D2 that intersects the first direction D1 and perpendicular to a third direction D3. The first, second, and third directions D1, D2, and D3 may be directions orthogonal to each other. A device isolation layer 11 may be provided in the first substrate 10. The device isolation layer 11 may define an active section of the first substrate 10.

In the explanation with reference to FIGS. 5, 6A, 6B, 7A, and 7B, the term “top surface” is defined to refer to a surface directed to the third direction D3, and the term “bottom surface” is defined to indicate a surface directed toward a direction opposite to the third direction D3.

The first substrate 10 may include a cell array region CAR and a contact region CCR. The contact region CCR may extend from the cell array region CAR in the first direction D1 or in a direction opposite to the first direction D1.

The first substrate 10 may be provided thereon with the peripheral circuit structure PS that includes peripheral transistors PTR, peripheral contact plugs 31, peripheral circuit lines 33 electrically connected through the peripheral contact plugs 31 to the peripheral transistors PTR, first bonding pads 35 electrically connected to the peripheral circuit lines 33, and a first dielectric layer 30 that surrounds the peripheral transistors PTR, the peripheral contact plugs 31, the peripheral circuit lines 33, and the first bonding pads 35. The peripheral transistors PTR may be disposed on the active section of the first substrate 10. The peripheral circuit lines 33 may correspond to the peripheral circuit lines 4110 of FIG. 3 or 4, and the first bonding pads 35 may correspond to the first bonding pads 4150 of FIG. 3 or 4.

For example, the peripheral contact plugs 31 may have a width in the first direction D1 or the second direction D2, and the width may increase in the third direction D3 (or with increasing distance from the first substrate 10). The peripheral contact plugs 31 and the peripheral circuit lines 33 may include a conductive material, such as metal.

The peripheral transistors PTR may constitute, for example, a decoder circuit (see 1100 of FIG. 1), a page buffer (see 1120 of FIG. 1), and a logic circuit (see 1130 of FIG. 1). For example, each of the peripheral transistors PTR may include a peripheral gate dielectric layer 21, a peripheral gate electrode 23, a peripheral capping pattern 25, a peripheral gate spacer 27, and peripheral source/drain sections 29. The peripheral gate dielectric layer 21 may be provided between the peripheral gate electrode 23 and the first substrate 10. The peripheral capping pattern 25 may be provided on the peripheral gate electrode 23. The peripheral gate spacer 27 may cover or overlap sidewalls of the peripheral gate dielectric layer 21, the peripheral gate electrode 23, and the peripheral capping pattern 25. The peripheral source/drain sections 29 may be provided in the first substrate 10 adjacent to opposite sides of the peripheral gate electrode 23. The peripheral circuit lines 33 and the first bonding pads 35 may be electrically connected through the peripheral contact plugs 31 to the peripheral transistors PTR. Each of the peripheral transistors PTR may be, for example, an NMOS transistor, a PMOS transistor, or a gate-all-around type transistor.

The first dielectric layer 30 may be provided on the first substrate 10. On the first substrate 10, the first dielectric layer 30 may cover or overlap the peripheral transistors PTR, the peripheral contact plugs 31, and the peripheral circuit lines 33. The first dielectric layer 30 may include a plurality of dielectric layers that constitute a multi-layered structure. For example, the first dielectric layer may include one or more of silicon oxide, silicon nitride, silicon oxynitride, and low-k dielectric materials. The first dielectric layer 30 may not cover or may not overlap top surfaces of the first bonding pads 35. The first dielectric layer 30 may have a top surface substantially coplanar with those of the first bonding pads 35.

The peripheral circuit structure PS may be provided thereon with a cell array structure CS including second bonding pads 45, bit lines BL, a stack structure ST, and a second substrate 100. The second bonding pads 45, the bit lines BL, the stack structure ST, and the second substrate 100 may respectively correspond to the second bonding pads 4250, the bit lines 4240, the gate stack structure 4210, and the common source line 4205 of FIG. 3 or 4.

The first dielectric layer 30 may be provided thereon with the second bonding pads 45 in contact with the first bonding pads 35 of the peripheral circuit structure PS, connection contact plugs 41, connection circuit lines 43 electrically connected through the connection contact plugs 41 to the second bonding pads 45, and a second dielectric layer 40 that covers or overlaps the second bonding pads 45, the connection contact plugs 41, and the connection circuit lines 43. The second dielectric layer 40 may include a plurality of dielectric layers that constitute a multi-layered structure. For example, the second dielectric layer 40 may include one or more of silicon oxide, silicon nitride, silicon oxynitride, and low-k dielectric materials.

For example, the connection contact plugs 41 may each have a width in the first direction D1 or the second direction D2 that decreases in the third direction D3. The connection contact plugs 41 and the connection circuit lines 43 may include a conductive material, such as metal.

The second dielectric layer 40 may not cover or may not overlap bottom surfaces of the second bonding pads 45. The second dielectric layer 40 may have a bottom surface substantially coplanar with those of the second bonding pads 45. The bottom surfaces of the second bonding pads 45 may be correspondingly in direct contact with the top surfaces of the first bonding pads 35. The first and second bonding pads 35 and 45 may include metal, such as copper (Cu), tungsten (W), aluminum (Al), nickel (Ni), or tin (Sn). For example, the first and second bonding pads 35 and 45 may include copper (Cu). The first and second bonding pads 35 and 45 may constitute a single unitary body without any interface therebetween. The first and second bonding pads 35 and 45 are illustrated to have their sidewalls aligned with each other, but the present inventive concepts are not limited thereto. For example, when viewed in plan, the first and second bonding pads 35 and 45 may have their sidewalls spaced apart from each other.

The second dielectric layer 40 may be provided in its upper portion with the bit lines BL and first, second, and third conductive lines CL1, CL2, and CL3 in contact with the connection contact plugs 41. For example, the bit lines BL and the first, second, and third conductive lines CL1, CL2, and CL3 may extend in the second direction D2 and may be spaced apart from each other in the first direction D1. The bit lines BL and the first, second, and third conductive lines CL1, CL2, and CL3 may include a conductive material, such as metal.

A third dielectric layer 51, a fourth dielectric layer 52, and a fifth dielectric layer 53 may be sequentially provided on the second dielectric layer 40. The fifth dielectric layer 53 may be provided thereon with a sixth dielectric layer 60 and the stack structure ST surrounded by the sixth dielectric layer 60. The stack structure ST may be a bottom surface (or one surface in contact with the fifth dielectric layer 53) substantially coplanar with that of the sixth dielectric layer 60. Each of the third, fourth, fifth, and sixth dielectric layers 51, 52, 53, and 60 may include a plurality of dielectric layers that constitute a multi-layered structure. For example, each of the third, fourth, fifth, and sixth dielectric layers 51, 52, 53, and 60 may include one or more of silicon oxide, silicon nitride, silicon oxynitride, and low-k dielectric materials.

Bit-line contact plugs BLCP may be provided to penetrate the third dielectric layer 51 and the fourth dielectric layer 52. The bit-line contact plugs BLCP may extend in the third direction D3, and may connect the bit lines BL to first vertical channel structures VS1 which will be discussed below.

First and second through contact plugs TCP1 and TCP2 may be provided to penetrate the third, fourth, and fifth dielectric layers 51, 52, and 53. The first and second through contact plugs TCP1 and TCP2 may extend in the third direction D3. The first through contact plug TCP1 may connect the second conductive line CL2 to a first through contact TC1 which will be discussed below. The second through contact plug TCP2 may connect the third conductive line CL3 to a second through contact TC2 which will be discussed below.

Cell contacts CC may be provided to penetrate the third, fourth, and fifth dielectric layers 51, 52, 53, and 60, and first and second through contacts TC1 and TC2 may be provided to penetrate the sixth dielectric layer 60. The cell contacts CC may extend in the third direction D3, and may connect the first conductive lines CL1 to subsequently described first and second gate electrodes ELa and ELb of the stack structure ST. Each of the cell contacts CC may penetrate one of the first and second interlayer dielectric layers ILDa and ILDb of the stack structure ST.

The first through contact TC1 may extend in the third direction D3, and may connect the second conductive line CL2 to the second substrate 100. The second through contact TC2 may extend in the third direction D3, and may connect the third conductive line CL3 to an input/output pad IOP which will be discussed below. The first through contact TC1 may penetrate a portion of the second substrate 100. A top surface and a portion of a sidewall of the first through contact TC1 may be in direct contact with the second substrate 100. The first through contact TC1 may be spaced apart in the first direction D1 from the stack structure ST and an outermost one of the cell contacts CC. The second through contact TC2 may be spaced apart in the first direction D1 from a sidewall of the second substrate 100. The second through contact TC2 may be spaced apart in the first direction D1 from the stack structure ST across the first through contact TC1. The second through contact TC2 may correspond to the input/output connection line 4265 of FIG. 3.

The first through contact TC1 and the second through contact TC2 may have their bottom surface located at a level different from those of bottom surfaces of the cell contacts CC and bottom surfaces of the first and second vertical channel structures VS1 and VS2. For example, the first through contact TC1 and the second through contact TC2 may have their bottom surface located at a level higher than those of bottom surfaces of the cell contacts CC and bottom surfaces of the first and second vertical channel structures VS1 and VS2.

The first through contact TC1 may have a top surface at a level lower than that of a top surface of the second substrate 100. The top surface of the second through contact TC2 may be located at the same level as the top surface of the second substrate 100. A diameter on the top surface of the first through contact TC1 and a diameter on the top surface of the second through contact TC2 may be respectively less than a diameter on a bottom surface of the first through contact TC1 and a diameter on a bottom surface of the second through contact TC2. The diameters of the first and second through contacts TC1 and TC2 may become minimum on the top surfaces of the first and second through contacts TC1 and TC2.

The cell contacts CC and the first and second through contacts TC1 and TC3 may be spaced apart from each other in the first direction D1. The bit-line contact plugs BLCP, the first and second through contact plugs TCP1 and TCP2, the cell contacts CC, and the first and second through contacts TC1 and TC2 may have their widths in the first direction D1 or the second direction D2 that decrease in the third direction D3. The bit-line contact plugs BLCP, the first and second through contact plugs TCP1 and TCP2, the cell contacts CC, and the first and second through contacts TC1 and TC2 may include a conductive material, such as metal.

The stack structure ST may be provided in plural. When viewed in plan, the plurality of stack structures ST may extend in the first direction D1 and may be spaced apart from each other in the second direction D2. For convenience of description, the following will explain a single stack structure ST, and the explanation may be identically applicable to other stack structures ST.

The stack structure ST may include a first stack structure ST1 and a second stack structure ST2. The first stack structure ST1 may include first interlayer dielectric layers ILDa and first gate electrodes ELa that are alternately stacked, and the second stack structure ST2 may include second interlayer dielectric layer ILDb and second gate electrodes ELb that are alternately stacked.

The second stack structure ST2 may be provided between the first stack structure ST1 and the first substrate 10. For example, the second stack structure ST2 may be provided on a bottom surface of a lowermost one of the first interlayer dielectric layers ILDa included in the first stack structure ST1. Although an uppermost one of the second interlayer dielectric layers ILDb included in the second stack structure ST2 is in contact with the lowermost one of the first interlayer dielectric layers ILDa included in the first stack structure ST1, the present inventive concepts are not limited thereto, and a single-layered dielectric layer may be provided between an uppermost one of the second gate electrodes ELb included in the second stack structure ST2 and a lowermost one of the first gate electrodes ELa included in the first stack structure ST1.

The first and second gate electrodes ELa and ELb may include, for example, at least one selected from doped semiconductor (e.g., doped silicon), metal (e.g., tungsten, copper, or aluminum), conductive metal nitride (e.g., titanium nitride or tantalum nitride), and transition metal (e.g., titanium or tantalum). The first and second interlayer dielectric layers ILDa and ILDb may include one or more of silicon oxide, silicon nitride, silicon oxynitride, and low-k dielectric materials. For example, the first and second interlayer dielectric layers ILDa and ILDb may include high-density plasma (HDP) oxide or tetraethylorthosilicate (TEOS).

On the contact region CCR, each of the first and second stack structures ST1 and ST2 may have a thickness in the third direction D3 that decreases with increasing distance from an outermost one of first vertical channel structures VS1 which will be discussed below. For example, each of the first and second stack structures ST1 and ST2 may have a stepwise structure along the first direction D1.

For example, the first gate electrodes ELa of the first stack structure ST1 and the second gate electrodes ELb of the second stack structure ST2 may have their lengths in the first direction D1 that increase with increasing distance from the first substrate 10. When viewed in plan as shown in FIG. 5, the first and second gate electrodes ELa and ELb may have their sidewalls that are spaced apart from each other at a regular interval along the first direction D1. A lowermost one of the second gate electrodes ELb included in the second stack structure ST2 may have a length in the first direction D1 less than any other of the second gate electrodes ELb included in the second stack structure ST2, and an uppermost one of the first gate electrodes ELa included in the first stack structure ST1 may have a length in the first direction D1 greater than any other of the first gate electrodes ELa included in the first stack structure ST1.

The first gate electrodes ELa and the second gate electrodes ELb may include first pad portions ELp1 and second pad portions ELp2 on the contact region CCR. The first pad portions ELp1 may be disposed at positions that are different horizontally and vertically. When viewed in plan, the second pad portion ELp2 may be disposed between two neighboring ones of the first pad portions ELp1. It is illustrated in drawings that only one second pad portion ELp2 is provided, but the second pad portion ELp2 may be provided in plural. A plurality of second pad portions ELp2 may be disposed at positions that are different horizontally and vertically. It is illustrated in drawings that one second pad portion ELp2 is disposed only on the first stack structure ST1, but a plurality of second pad portions ELp2 may be disposed one or both of the first stack structure ST1 and the second stack structure ST2. The first pad portions ELp1 and the second pad portions ELp2 may constitute a stepwise structure along the first direction D1. Each of the second pad portions ELp2 may have a length in the first direction D1 greater than a length in the first direction D1 of each of the first pad portions ELp1. The cell contacts CC may penetrate one of the first and second interlayer dielectric layers ILDa and ILDb to come into contact with the first pad portions ELp1 of the first and second gate electrodes ELa and ELb. It is illustrated that the cell contacts CC are not disposed on zones that do not vertically overlap the second pad portions ELp2, but the present inventive concepts are not limited thereto. Although not shown, the cell contacts CC may penetrate one of the first and second interlayer dielectric layers ILDa and ILDb to come into contact with the second pad portions ELp2 of the first and second gate electrodes ELa and ELb. This configuration mentioned above may be changed in accordance with design of a three-dimensional semiconductor memory device which is intended to fabricate.

The first and second interlayer dielectric layers ILDa and ILDb may be provided between the first and second gate electrodes ELa and ELb, and may each have a sidewall aligned with that of an overlaying one of the first and second gate electrodes ELa and ELb. For example, likewise the first and second gate electrodes ELa and ELb, the first and second interlayer dielectric layers ILDa and ILDb may have their lengths in the first direction D1 that increase with increasing distance from the first substrate 10. A lowermost one of the second interlayer dielectric layers ILDb may have a thickness in the third direction D3 greater than a thickness of any other of the second interlayer dielectric layers ILDb, and an uppermost one of the first interlayer dielectric layers ILDa may have a thickness in the third direction D3 less than a thickness of any other of the first interlayer dielectric layers ILDa, but the present inventive concepts are not limited thereto.

When viewed in plan, a vertical separation dam structure DAM may be disposed in the second pad portions ELp2. The vertical separation dam structure DAM may be disposed in a vertical separation dam structure trench DAMH that penetrates in the third direction D3 through the fifth dielectric layer 53, the sixth dielectric layer 60, and the stack structure ST. The vertical separation dam structure trench DAMH may further penetrate a portion of the second substrate 100. The vertical separation dam structure DAM may extend in the third direction D3. The vertical separation dam structure DAM may have a width in the first direction D1 or the second direction that decreases in the third direction D3. The vertical separation dam structure DAM may penetrate the fifth dielectric layer 53, the sixth dielectric layer 60, and the stack structure ST that are provided on a zone that vertically penetrates the second pad portions ELp2. The vertical separation dam structure DAM may further penetrate a portion of the second substrate 100. Referring to FIG. the vertical separation dam structure DAM may have a tetragonal annular shape when viewed in plan. According to some embodiments, the vertical separation dam structure DAM may have a polygonal or a circular annular shape when viewed in plan. According to some embodiments, the vertical separation dam structure DAM may have a hollow tetragonal cylindrical shape. According to some embodiments, the vertical separation dam structure DAM may have a hollow polygonal or circular cylindrical shape. The vertical separation dam structure DAM may be surrounded by the first and second gate electrodes ELa and ELb and the first and second interlayer dielectric layers ILDa and ILDb.

When viewed in plan, through structures CAP, a mold structure MS, and a residual lower sacrificial layer 101a may be disposed in an inner perimeter of the vertical separation dam structure DAM.

The through structures CAP may be surrounded by the vertical separation dam structure DAM. The through structures CAP may be spaced apart from the first and second gate electrodes ELa and ELb across the vertical separation dam structure DAM. The through structures CAP may be spaced apart from each other in the first direction D1 and the second direction D2. Each of the through structures CAP may have a first distance H1 in the second direction D2 from an adjacent through structure CAP and a second distance H2 in the first direction D1 from another through structure CAP. The first distance H1 may be greater the second distance H2. This, however, is by way of example only, and in some embodiments, the second distance H2 may be greater than the first distance H1. This configuration mentioned above may be changed in accordance with design of a three-dimensional semiconductor memory device which is intended to fabricate. It is illustrated in drawings that four through structures CAP are disposed in the vertical separation dam structure DAM, but no limitation is imposed on the number of the through structures CAP. In some embodiments, there may be an even number of the through structures CAP. For example, when viewed in plan, the vertical separation dam structure DAM may be provided therein with two, four, six, or any even number of the through structures CAP. This configuration mentioned above may be changed in accordance with design of a three-dimensional semiconductor memory device which is intended to fabricate.

The through structures CAP may extend in the third direction D3. The through structures CAP may have a width in the first direction D1 or the second direction D2 that decreases in the third direction D3.

The mold structure MS may include first residual interlayer dielectric layers 111a and first residual sacrificial layers 121a that are alternately stacked. Each of the residual interlayer dielectric layers 111a may be located at the same level as that of each of the first interlayer dielectric layers ILDa across the vertical separation dam structure DAM. The first residual interlayer dielectric layers 111a may include the same material as that of the first interlayer dielectric layers ILDa. Each of the first residual sacrificial layers 121a may be located at the same level as that of the first gate electrode ELa adjacent thereto across the vertical separation dam structure DAM. The first residual sacrificial layers 121a may include a material different from that of the first gate electrodes ELa. The first residual sacrificial layers 121a may include, for example, silicon nitride. Although not shown, when the second pad portions ELp2 are disposed on the second stack structure ST2, the mold structure MS may further include second residual interlayer dielectric layers (not shown) located at the same levels as those of the second interlayer dielectric layers ILDb adjacent thereto across the vertical separation dam structure DAM, and may also further include second residual sacrificial layers (not shown) located at the same levels as those of the second gate electrodes ELb adjacent thereto across the vertical separation dam structure DAM. The mold structure MS may be surrounded by the vertical separation dam structure DAM. In some embodiments, the mold structure MS may have an outer sidewall in contact with an inner sidewall of the vertical separation dam structure DAM. In some embodiments, an insulator may be interposed between the outer sidewall of the mold structure MS and the inner sidewall of the vertical separation dam structure DAM.

The residual lower sacrificial layer 101a may be disposed on an uppermost one of the first residual interlayer dielectric layers 111a. The residual lower sacrificial layer 101a may be formed of, for example, silicon nitride. According to some embodiments, the residual lower sacrificial layer 110 may be formed of a plurality of dielectric layers that constitute a multi-layered structure.

The through structures CAP may be disposed in through structure holes CAPH that penetrate in the third direction D3 through the fifth dielectric layer 53, the sixth dielectric layer 60, the mold structure MS, and the residual lower sacrificial layer 101a. The through structure holes CAPH may further penetrate a portion of the second substrate 100. The through structure holes CAPH may extend in the third direction D3. The through structure CAP may penetrate in the third direction D3 through the fifth dielectric layer 53, the sixth dielectric layer 60, the mold structure MS, and the residual lower sacrificial layer 101a. The through structures CAP may further penetrate a portion of the second substrate 100. The vertical separation dam structure DAM and the through structures CAP may have their bottom surfaces coplanar with that of the fifth dielectric layer 53 (or a top surface of the fourth dielectric layer 52), but the present inventive concepts are not limited thereto. The bottom surfaces of the vertical separation dam structure DAM and the through structures CAP may be in contact with the top surface of the fourth dielectric layer 52.

Through structure contact plugs CAPCP may be provided to penetrate the third dielectric layer 51 and the fourth dielectric layer 52. The through structure contact plugs CAPCP may extend in the third direction D3 and may connect the first conductive lines CL1 to the through structures CAP.

On the cell array region CAR, first vertical channel structures VS1 may be provided in vertical channel holes CH that penetrate in the third direction D3 through the stack structure ST. When viewed in plan as shown in FIG. 5, the first vertical channel structures VS1 may be arranged in a zigzag fashion along the first direction D1 or the second direction D2. The first vertical channel structures VS1 may correspond to the memory channel structures 4220 of FIG. 3 or 4. The first vertical channel structures VS1 may correspond to channels of the first transistors LT1 and LT2, channels of the memory cell transistors MCT, and channels of the second transistors UT1 and UT2 of FIG. 1.

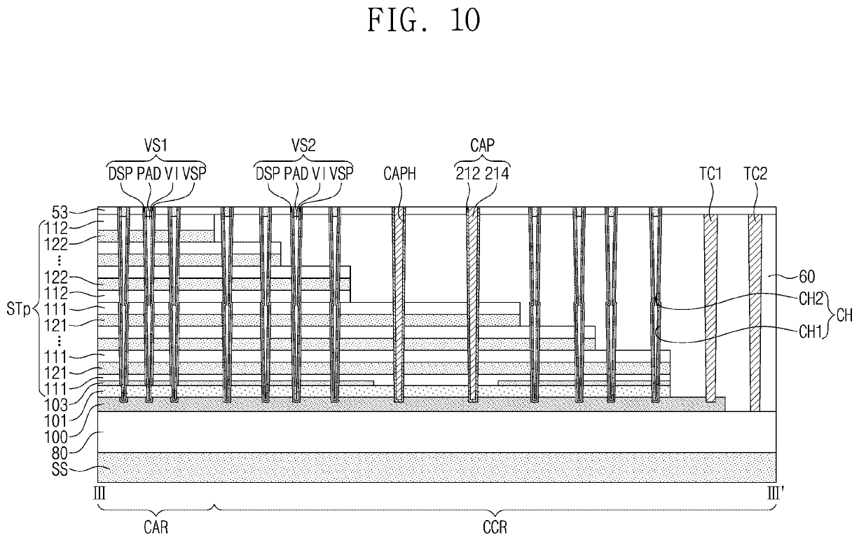

On the contact region CCR, second vertical channel structures VS2 may be provided in vertical channel holes CH that penetrate in the third direction D3 through at least a portion of the stack structure ST, the fifth dielectric layer 53, and the sixth dielectric layer 60. The second vertical channel structures VS2 are not appear on the cross-sectional view taken along line I-I′ of FIG. 5, but for clarity of description, FIG. 6A uses solid lines to represent the second vertical channel structures VS2. For the same reason, FIGS. 10, 12, 14A, 16A, and 17 also use solid lines to denote the second vertical channel structures VS2, and a repetitive description thereof will be omitted. The second vertical channel structures VS2 may penetrate the first pad portions ELp1 of the first and second gate electrodes ELa and ELb. Although not shown, the second vertical channel structures VS2 may penetrate the second pad portions ELp2 of the first and second gate electrodes ELa and ELb. When viewed in plan as shown in FIG. 5, the second vertical channel structures VS2 may be provided around the cell contacts CC. The second vertical channel structures VS2 may be formed simultaneously with the first vertical channel structures VS1, and may have a structure substantially the same as that of the first vertical channel structures VS1. However, the second vertical channel structures VS2 may not be provided in accordance with some embodiments.

The vertical channel holes CH may include first vertical channel holes CH1 and second vertical channel holes CH1 connected in the third direction D3 to the first vertical channel holes CH1. Each of the first and second vertical channel holes CH1 and CH2 may have a width in the first direction D1 or the second direction D2 that decreases in the third direction D3. The first and second vertical channel holes CH1 and CH2 may have their diameters that are different from each other at a boundary where the first and second vertical channel holes CH1 and CH2 are spatially connected to each other. For example, each of the second vertical channel holes CH2 may have at its upper portion a diameter less than a diameter at a lower portion of each of the first vertical channel holes CH1.

Each of the first and second vertical channel structures VS1 and VS2 may have a sidewall that has a step difference at a boundary between the first and second vertical channel holes CH1 and CH2. The present inventive concepts, however, are not limited thereto, and differently from that shown, the sidewall of each of the first and second vertical channel structures VS1 and VS2 may have three or more step differences at different levels or may be flat without the step difference.

Each of the first and second vertical channel structures VS1 and VS2 may include a conductive pad PAD adjacent to the fifth dielectric layer 53, a data storage pattern DSP that conformally covers or overlaps an inner sidewall of each of the first and second vertical channel holes CH1 and CH2 (or that is adjacent to the stack structure ST), a vertical semiconductor pattern VSP that conformally covers or overlaps a sidewall of the data storage pattern DSP, and a buried dielectric pattern VI that fills an inner space, which is surrounded by the vertical semiconductor pattern VSP and the conductive pad PAD, of each of the first and second vertical channel holes CH1 and CH2. The vertical semiconductor pattern VSP may be surrounded by the data storage pattern DSP. The first and second vertical channel structures VS1 and VS2 may each have a bottom surface that has, for example, a circular shape, an oval shape, or a bar shape. Although not shown in figures, the second vertical channel structures VS2 may not include any of the conductive pad PAD, the data storage pattern DSP, the vertical semiconductor pattern VSP, and the buried dielectric pattern VI. In some embodiments, the second vertical channel structures VS2 may include a material different from that of the first vertical channel structures VS1. The second vertical channel structures VS2 may include only a dielectric material, such as silicon oxide, silicon nitride, or silicon oxynitride. The present inventive concepts, however, are not limited thereto, and the second vertical channel structures VS2 may include various materials. This configuration mentioned above may be changed in accordance with design of a three-dimensional semiconductor memory device which is intended to fabricate.

The vertical semiconductor pattern VSP may be provided between the data storage pattern DSP and the buried dielectric pattern VI and between the data storage pattern DSP and the conductive pad PAD. The vertical semiconductor pattern VSP may have a macaroni shape or a pipe shape whose top end is closed. The data storage pattern DSP may have a macaroni shape or a pipe shape whose top end is closed. The vertical semiconductor pattern VSP may include, for example, an impurity-doped semiconductor material, an impurity-undoped intrinsic semiconductor material, or a polycrystalline semiconductor material. The conductive pad PAD may include, for example, an impurity-doped semiconductor material or a conductive material.

When viewed in plan as shown in FIG. 5, a first trench TR1 and second trenches TR2 may be provided to extend in the first direction D1 and to run across the stack structure ST. The first trench TR1 may be provided in the cell array region CAR, and the second trenches TR2 may be provided to extend from the cell array region CAR toward the contact region CCR. Although not shown, in some embodiments, the first trench TR1 may not be disposed on a boundary between the cell array region CAR and the contact region CCR. For example, the first trench TR1 may not extend from the cell array region CAR toward the contact region CCR. The first and second trenches TR1 and TR2 may have their widths in the second direction D2 that decrease with increasing distance from the first substrate 10.

A first separation pattern SP1 may be provided to fill the first trench TR1, and second separation patterns SP2 may be provided to fill the second trenches TR2. The first and second separation patterns SP1 and SP2 may have their plate shapes that extend in the first and third directions D1 and D3. The second separation patterns SP2 may correspond to the separation structures 4230 of FIG. 3 or 4. Each of the second separation patterns SP2 may have a length in the first direction D1 greater than a length in the first direction D1 of the first separation pattern SP1. The first and second separation patterns SP1 and SP2 may have their sidewalls in contact those of the first and second gate electrodes ELa and ELb of the stack structure ST and those of the first and second interlayer dielectric layers ILDa and ILDb of the stack structure ST. The first and second separation patterns SP1 and SP2 may include a dielectric material, such as silicon oxide.

The second separation patterns SP2 may have their bottom surfaces substantially coplanar with a bottom surface of the fourth dielectric layer 52 (or a top surface of the third dielectric layer 51), but the present inventive concepts are not limited thereto. According to some embodiments, the second separation patterns SP2 may have their bottom surfaces substantially coplanar with a bottom surface of the third dielectric layer 51 (or a top surface of the second dielectric layer 40). The bottom surfaces of the second separation patterns SP2 may be located at a level lower than that of the bottom surfaces of the first and second vertical channel structures VS1 and VS2. In addition, the second separation patterns SP2 may have their top surfaces located at a level higher than that of top surfaces of the first and second vertical channel structures VS1 and VS2.

When the stack structure ST is provided in plural, the first separation pattern SP1 or one of the second separation patterns SP2 may be provided between the stack structures ST that are arranged along the second direction D2. For example, the stack structures ST may be spaced apart from each other in the second direction D2 across the first separation pattern SP1 or one of the second separation patterns SP2. Each of the first and second separation patterns SP1 and SP2 may be provided in plural, and the plurality of first separation patterns SP1 may be spaced apart in the second direction D2 from the plurality of second separation patterns SP2 across one of the stack structures ST.

The vertical separation dam structure DAM, the through structures CAP, and the mold structure MS may be disposed between neighboring second separation patterns SP2, and may be spaced apart in the second direction D2 from the second separation patterns SP2.

The second substrate 100 may be provided on the stack structure ST. The second substrate 100 may have a plate shape that extends in the first direction D1 and the second direction D2. A bottom surface of the second substrate 100 may be parallel to a top surface of the first substrate 10. The second substrate 100 may extend from the cell array region CAR toward the contact region CCR. The second substrate 100 may not be provided on a portion of the contact region CCR. The second substrate 100 may be a semiconductor substrate including a semiconductor material. The second substrate 100 may include, for example, at least one selected from silicon (Si), germanium (Ge), silicon-germanium (SiGe), gallium-arsenic (GaAs), indium-gallium-arsenic (InGaAs), aluminum-gallium-arsenic (AlGaAs), and a mixture thereof.

A source structure SC may be provided between the stack structure ST and the second substrate 100. The source structure SC may have a plate shape that extends in the first and second directions D1 and D2 parallel to the top surface of the first substrate 10 (or a top surface of the stack structure ST and the bottom surface of the second substrate 100). The source structure SC may overlap in the third direction D3 with the second substrate 100. A portion of the second substrate 100 may not overlap in the third direction D3 with the source structure SC, and may directly contact the six dielectric layer 60 and the first through contact TC1.

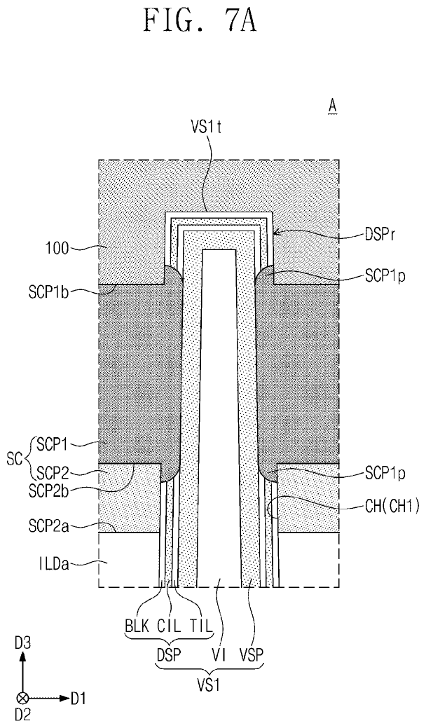

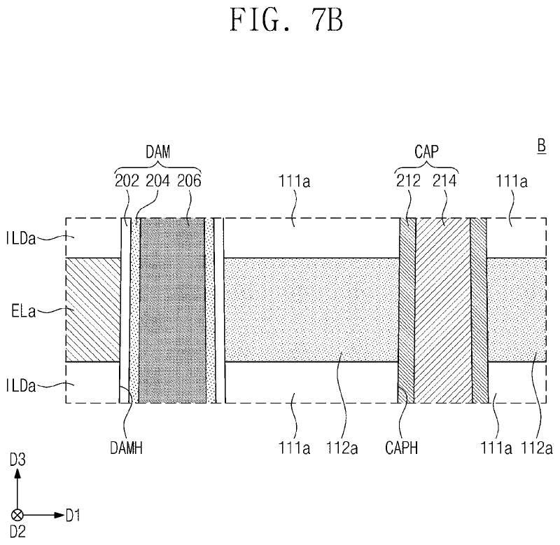

Each of the first and second vertical channel structures VS1 and VS2 may penetrate the source structure SC and at least a portion of the second substrate 100. Each of the first and second vertical channel structures VS1 and VS2 may have an upper portion in contact with the second substrate 100. As discussed below with reference to FIG. 7A, the vertical semiconductor pattern VSP of each of the first and second vertical channel structures VS1 and VS2 be in contact with a portion of the source structure SC.

The vertical separation dam structure DAM and the through structures CAP may have their upper portions in contact with the second substrate 100. The vertical separation dam structure DAM and the through structures CAP may have their top surfaces at a level higher than that of the bottom surface of the second substrate 100. The vertical separation dam structure DAM and the through structures CAP may have their top surfaces at a level higher than that of a top surface of the source structure SC.

The through structures CAP may have their lateral surfaces surrounded by the residual lower sacrificial layer 101a, the mold structure MS, the sixth dielectric layer 60, and the fifth dielectric layer 53. For example, the lateral surfaces of the through structures CAP may be surrounded by insulators, except portions of upper portions of the through structures CAP in contact with the second substrate 100.

There may constitute a pair of two through structures CAP that are spaced apart from each other in the first direction D1 or the second direction D2. In some embodiments, when the first distance H1 is less than the second distance H2, there may be constituted a pair of two through structures CAP that are spaced apart from each other in the second direction D2. In another embodiment, when the second distance H2 is less than the first distance H1, there may be constituted a pair of two through structures CAP that are spaced apart from each other in the first direction D1. A pair of through structures CAP may be provided therebetween with dielectric materials of the residual lower sacrificial layer 101a, the mold structure MS, the sixth dielectric layer 60, and the fifth dielectric layer 53. A positive voltage may be applied to one of a pair of through structures CAP, and a negative voltage may be applied to the other of a pair of through structures CAP. In this case, negative charges may be gathered around the one through structure CAP to which the positive voltage is applied, and positive charges may be gathered around the other through structure CAP to which the negative voltage is applied. Therefore, dielectric materials between a pair of through structures CAP and a pair of through structures CAP may serve as capacitors. A pair of through structures CAP may serve a capacitor electrode For example, capacitors may be provided on the cell array structure CS, and the capacitors may include dielectric materials interposed between a pair of through structures CAP and a pair of through structures CAP spaced apart therefrom.

The source structure SC may include a first source conductive pattern SCP1 on the stack structure ST and a second source conductive pattern SCP2 between the stack structure ST and the first source conductive pattern SCP1. The second source conductive pattern SCP2 may be provided between the first source conductive pattern SCP1 and the uppermost first interlayer dielectric layer ILDa of the first stack structure ST1. The second source conductive pattern SCP2 may directly contact the first source conductive pattern SCP1. The first source conductive pattern SCP1 may have a thickness in the third direction D3 greater than a thickness in the third direction D3 of the second source conductive pattern SCP2. The source structure SC may include an impurity-doped semiconductor material. The source structure SC may include, for example, a semiconductor material doped with impurities having the same conductivity type as that of the second substrate 100. For example, an impurity concentration of the first source conductive pattern SCP1 may be greater than that of the second source conductive patterns SCP2 and that of the second substrate 100.

A seventh dielectric layer 80 may be provided on the second substrate 100 and the sixth dielectric layer 60. A top surface of the seventh dielectric layer 70 may be substantially flat. A bottom surface of the seventh dielectric layer 80 may be substantially coplanar with the top surface of the second through contact TC2.

An input/output pad IOP may be disposed to penetrate the seventh dielectric layer 80. The input/output pad IOP may include an input/output via portion 92 in the seventh dielectric layer 80 and an input/output pad portion 94 on the top surface of the seventh dielectric layer 80. The input/output pad IOP may vertically overlap the second through contact TC2. A bottom surface of the input/output pad IOP (or a bottom surface of the input/output via portion 92) may be in contact with the top surface of the second through contact TC2. The input/output pad IOP may be electrically connected to the second through contact TC2. The input/output pad IOP may be electrically connected through the second through contact TC2 to the peripheral transistors PTR of the peripheral circuit structure PS. The input/output via portion 92 may include, for example, tungsten (W). The input/output pad portion 94 may include, for example, aluminum (Al). The input/output pad IOP may correspond to the input/output pad 1101 of FIG. 1 or one of the input/output pads 2210 of FIG. 3 or 4.

When viewed in plan, a three-dimensional semiconductor memory device according to the present inventive concepts may be configured such that the vertical separation dam structure DAM may be disposed on the second pad portions ELp2, and that the mold structure MS including a dielectric material may be disposed in an inner perimeter of the vertical separation dam structure DAM. A pair of through structures CAP spaced apart from each other in the first direction D1 or the second direction D2 may penetrate the mold structure MS. A pair of through structures CAP may be surrounded by a dielectric material, and thus the pair of through structures CAP and the dielectric material may serve as a capacitor in the cell array structure CS. Accordingly, the number of capacitors disposed on the peripheral circuit structure PS may be reduced to increase integration of a three-dimensional semiconductor memory device.

In addition, as the peripheral circuit structure PS vertically penetrates the through structures CAP, a reduced electrical connection path may be provided between the peripheral transistors PTR and a capacitor electrode. In conclusion, a three-dimensional semiconductor memory device may improve in reliability and electrical properties.

FIG. 7A illustrates an enlarged view of section A depicted in FIG. 6A, partially showing a three-dimensional semiconductor memory device according to some embodiments of the present inventive concepts.

Referring to FIGS. 6A and 7A, there may be illustrated one of the first vertical channel structures VS1 each including a portion of the source structure SC, a portion of the second substrate 100, the data storage pattern DSP, the vertical semiconductor pattern VSP, the buried dielectric pattern VI, and a lower data storage pattern DSPr. A single vertical channel hole CH and a single first vertical channel structure VS1 will be discussed below for convenience of description, and the following description may be identically applicable to other vertical channel structures CH and other first vertical channel structures VS1.

The first vertical channel structure VS1 may have a top surface VS It in contact with the second substrate 100. The top surface VS It of the first vertical channel structure VS1 may correspond to a top surface of the lower data storage pattern DSPr. The top surface VS It of the first vertical channel structure VS1 may be located at a level higher than that of a top surface SCP1b of the first source conductive pattern SCP1.

The data storage pattern DSP may include a blocking dielectric layer BLK, a charge storage layer CIL, and a tunneling dielectric layer TIL that are sequentially formed on an inner sidewall of the vertical channel hole CH. The blocking dielectric layer BLK may be adjacent to the stack structure ST or the source structure SC, and the tunneling dielectric layer TIL may be adjacent to the vertical semiconductor pattern VSP. The charge storage layer CIL may be interposed between the blocking dielectric layer BLK and the tunneling dielectric layer TIL. The blocking dielectric layer BLK, the charge storage layer CIL, and the tunneling dielectric layer TIL may extend in the third direction D3 between the stack structure ST and the vertical semiconductor pattern VSP. The data storage pattern DSP may store and/or change data by using Fowler-Nordheim tunneling induced by a voltage difference between the vertical semiconductor pattern VSP and the first and second gate electrodes ELa and ELb. For example, the blocking dielectric layer BLK and the tunneling dielectric layer TIL may include silicon oxide, and the charge storage layer CIL may include silicon nitride or silicon oxynitride.

The first source conductive pattern SCP1 of the source structure SC may be in contact with the vertical semiconductor pattern VSP, and the second source conductive pattern SCP2 may be spaced apart from the vertical semiconductor pattern VSP across the data storage pattern DSP. The first source conductive pattern SCP1 may be spaced apart from the buried dielectric pattern VI across the vertical semiconductor pattern VSP.

For example, the first source conductive pattern SCP1 may include protrusions SCP1p located at a level lower than that of a top surface SCP2b of the second source conductive pattern SCP1 or higher than that of the top surface SCP1b of the first source conductive pattern SCP1. The protrusions SCP1p may be located at a level higher than that of a bottom surface SCP2a of the second source conductive pattern SCP2. For example, the protrusions SCP1p may each have a curved shape at a surface in contact with the data storage pattern DSP or the lower data storage pattern DSPr.

FIG. 7B illustrates an enlarged view of section B depicted in FIG. 6A, partially showing a three-dimensional semiconductor memory device according to some embodiments of the present inventive concepts.

Referring to FIGS. 6A and 7B, the vertical separation dam structure DAM may be provided in the vertical separation dam structure trench DAMH. The vertical separation dam structure DAM may include a first protection layer 202 that conformally covers or overlaps an inner sidewall and a bottom surface of the vertical separation dam structure trench DAMH, a second protection layer 204 that conformally covers or overlaps a sidewall of the first protection layer 202, and a buried pattern 206 that fills an inner space of the vertical separation dam structure trench DAMH surrounded by the second protection layer 204.

The first protection layer 202 may have an outer sidewall in contact with the first interlayer dielectric layer ILDa, the first gate electrodes ELa, the mold structure MS, the residual lower sacrificial layer 101a, the source structure SC, and the second substrate 100. This, however, is by way of example only, and the first protection layer 202 may be provided on its outer sidewall with an additional dielectric layer (a silicon oxide layer, a silicon nitride layer, or a silicon oxynitride layer). Although not shown, when the second pad portions ELp2 are disposed on the second stack structure ST2, the outer sidewall of the first protection layer 202 may additionally be in contact with the second interlayer dielectric layer ILDb and the second gate electrodes ELb.

The first protection layer 202 may include, for example, a silicon oxide layer or a silicon oxynitride layer. The second protection layer 204 may include, for example, a silicon nitride layer. The buried pattern 206 may include, for example, an impurity-doped semiconductor material, an impurity-undoped intrinsic semiconductor material, or a polycrystalline semiconductor material.

The through structures CAP may each include a barrier layer 212 that conformally covers or overlaps an inner sidewall and a bottom surface of the through structure hole CAPH and a conductive pattern 214 that fills an inner space of the through structure hole CAPH surrounded by the barrier layer 212.

The barrier layer 212 may have an outer sidewall in contact with the first interlayer dielectric layer ILDa, the first gate electrodes ELa, the mold structure MS, the residual lower sacrificial layer 101a, the source structure SC, and the second substrate 100. Although not shown, when the second pad portions ELp2 are disposed on the second stack structure ST2, the outer sidewall of the barrier layer 212 may additionally be in contact with the second interlayer dielectric layer ILDb and the second gate electrodes ELb.

The barrier layer 212 may include, for example, conductive metal nitride. For example, the barrier layer 212 may include titanium nitride or tantalum nitride. The conductive pattern 214 may include, for example, at least one selected from doped semiconductor (e.g., doped silicon), metal (e.g., tungsten, copper, or aluminum), and transition metal (e.g., titanium or tantalum). For example, the conductive pattern 214 may include tungsten (W).

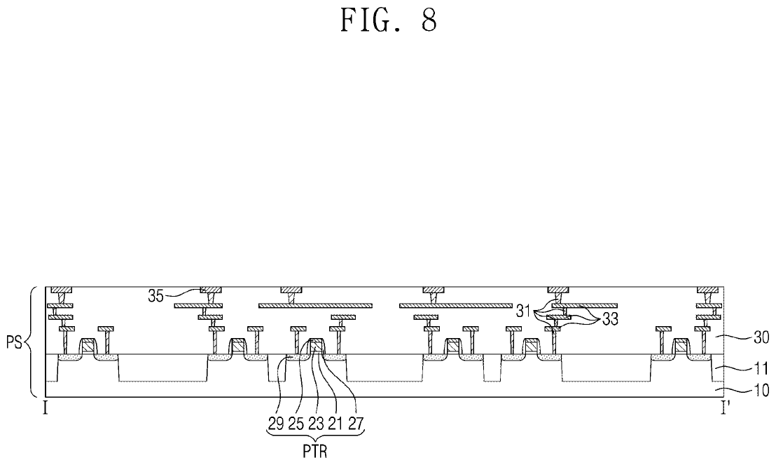

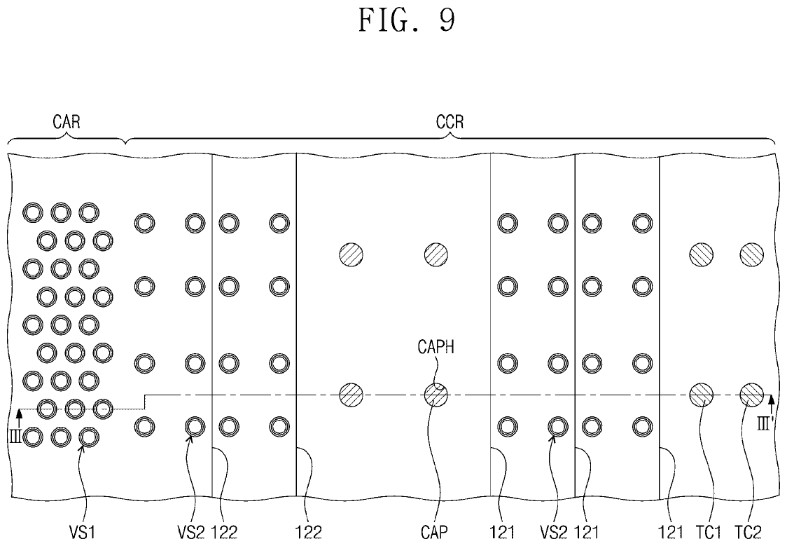

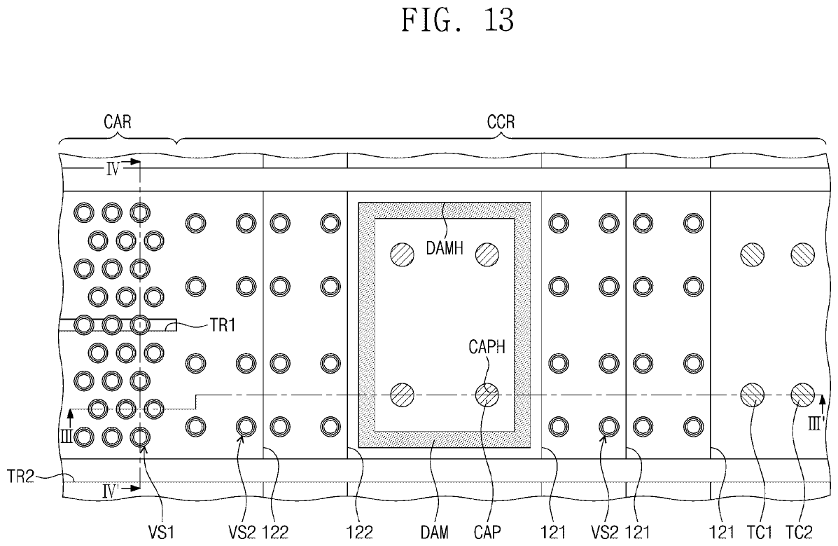

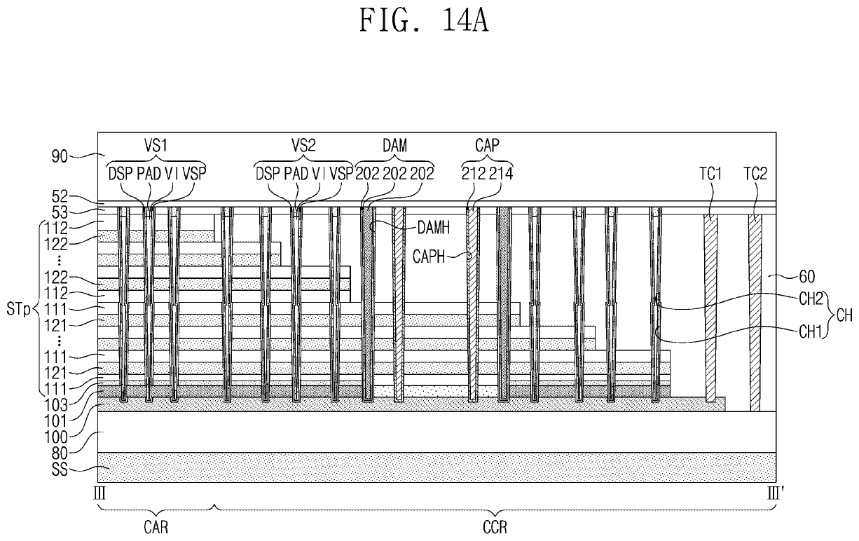

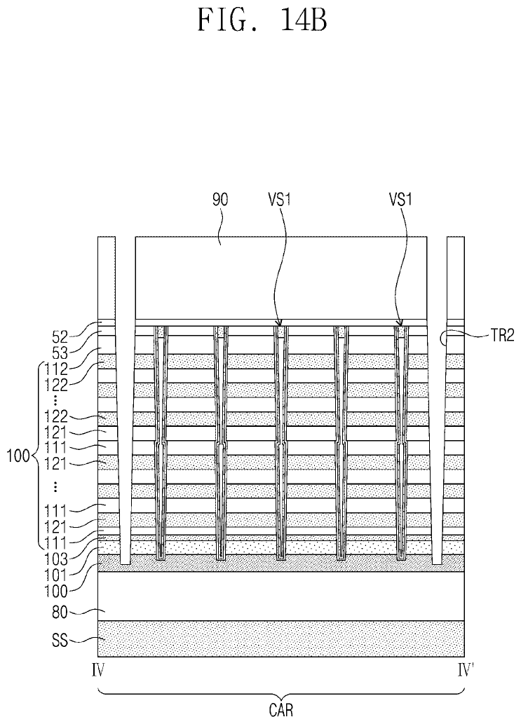

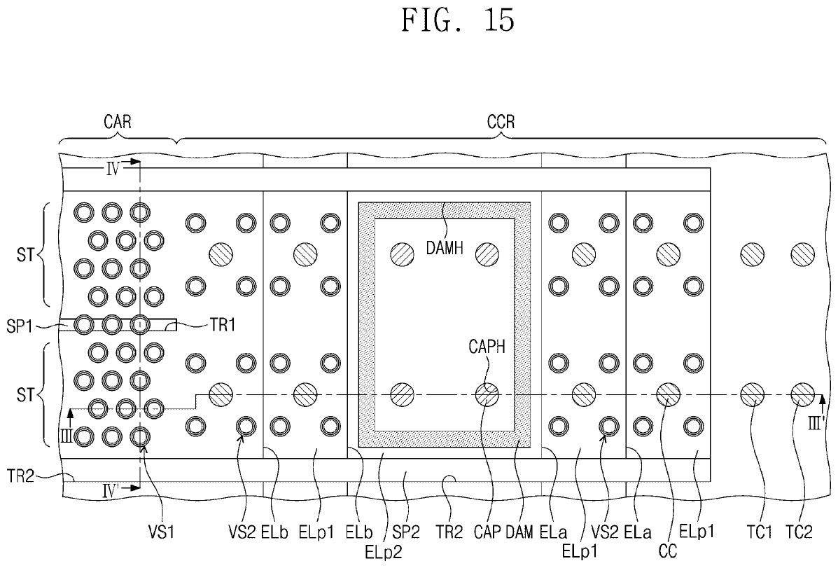

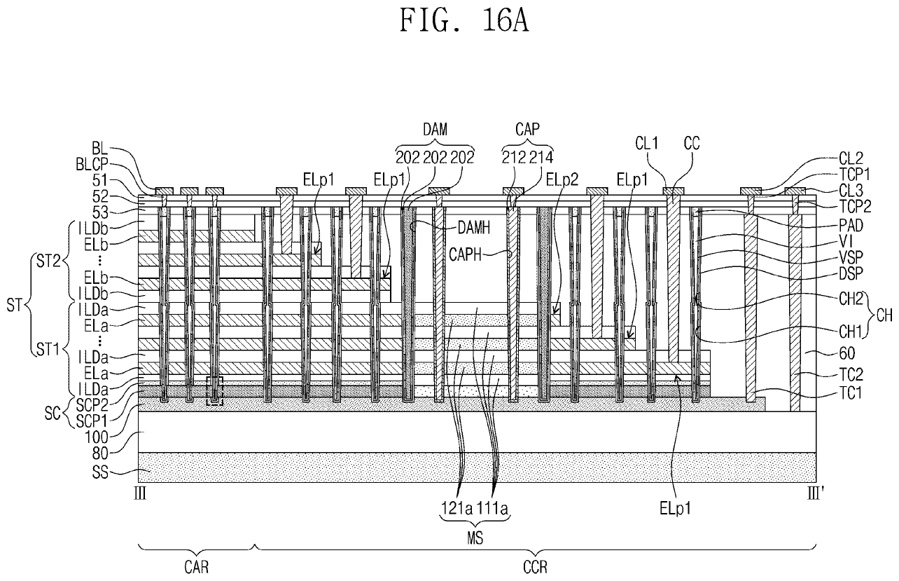

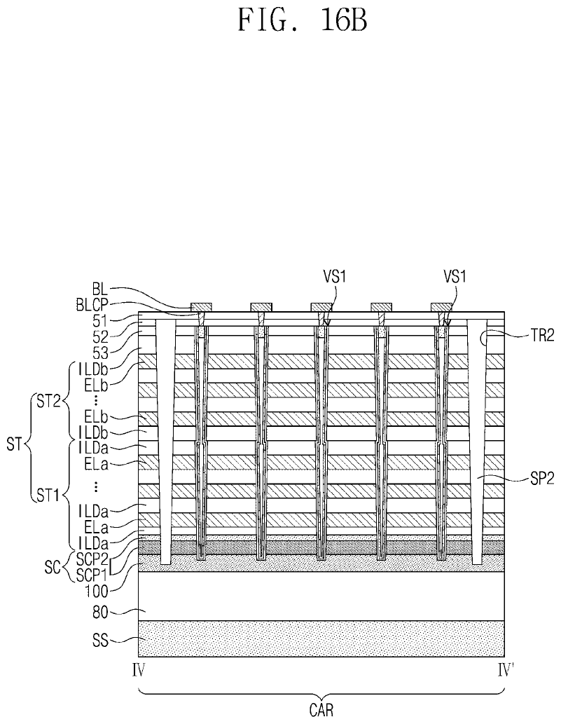

FIG. 8 illustrates a cross-sectional view taken along line II-II′ of FIG. 5, showing a method of fabricating a three-dimensional semiconductor memory device according to some embodiments of the present inventive concepts. FIGS. 9, 11, 13, and 15 illustrate plan views showing a method of fabricating a three-dimensional semiconductor memory device according to some embodiments of the present inventive concepts. FIGS. 10, 12, 14A, 16A, and 17 illustrate cross-sectional views taken along line III-III′ of FIG. 9. 11, 13, or 15, showing a method of fabricating a three-dimensional semiconductor memory device according to some embodiments of the present inventive concepts. FIGS. 14B and 16B illustrate cross-sectional views taken along line IV-IV′ of FIG. 13 or 15, showing a method of fabricating a three-dimensional semiconductor memory device according to some embodiments of the present inventive concepts.

It will be hereinafter described about a method of fabricating a three-dimensional semiconductor memory device according to some embodiments of the present inventive concepts with reference to FIGS. 8 to 17.

Referring to FIG. 8, a peripheral circuit structure PS may be formed on a first substrate 10. The formation of the peripheral circuit structure PS may include forming a device isolation layer 11 in the first substrate 10, forming peripheral transistors PTR on an active section of the first substrate 10 defined by the device isolation layer 11, forming peripheral contact plugs 31, peripheral circuit lines 33, and first bonding pads 35 electrically connected to the peripheral transistors PTR, and forming a first dielectric layer 30 that covers or overlaps the device isolation layer 11, the peripheral transistors PTR, the peripheral contact plugs 31, the peripheral circuit lines 33, and the first bonding pads 35.

The first bonding pads 35 may have their top surfaces substantially coplanar with that of the first dielectric layer 30. In this description below, the phrase “substantially coplanar with” may mean that surfaces are approximately in a same plane such that a planarization process can be performed. The planarization process may include, for example, a chemical mechanical polishing (CMP) process or an etch-back process.

Referring to FIGS. 9 and 10, a sacrificial substrate SS may be provided which includes a cell array region CAR and a contact region CCR. The sacrificial substrate SS may be, for example, a silicon substrate, but the present inventive concepts are not limited thereto.

In the following explanation with reference to FIGS. 9 to 17, the term “top surface” may refer to a bottom surface when viewed from the three-dimensional semiconductor memory device that has been fabricated as shown in FIGS. 6A and 6B, and the term “bottom surface” may refer to a top surface when viewed from the three-dimensional semiconductor memory device that has been fabricated as shown in FIGS. 6A and 6B.

A seventh dielectric layer 80, a second substrate 100, a lower sacrificial layer 101, and a lower semiconductor layer 103 may be sequentially formed on the sacrificial substrate SS. For the seventh dielectric layer 80, the term “upper portion” may only indicate the expression of being provided on an upper portion of the stack structure ST when viewed from the three-dimensional semiconductor memory device that has been fabricated as shown in FIGS. 6A and 6B, and the present inventive concepts are not limited to the denotative meaning of “upper portion” in explaining the following fabrication method. The second substrate 100 and the lower semiconductor layer 103 may be formed of an impurity-doped semiconductor material. The lower sacrificial layer 101 may be formed of, for example, silicon nitride. According to some embodiments, the lower sacrificial layer 101 may be formed of a plurality of dielectric layers that constitute a multi-layered structure. The lower semiconductor layer 103 may not be formed on a zone that vertically overlaps the second pad portions ELp2 discussed above in FIG. 6A. The zone where the lower semiconductor layer 103 is not formed may be a zone on which will be formed the mold structure MS discussed above in FIG. 6A.

A preliminary stack structure STp may be formed to include first and second interlayer dielectric layers 111 and 112 and first and second sacrificial layers 121 and 122 that are alternately stacked on the lower semiconductor layer 103. The first and second sacrificial layers 121 and 122 may be formed of a dielectric material different from that of the first and second interlayer dielectric layers 111 and 112. The first and second sacrificial layers 121 and 122 may be formed of a material that can be etched with etch selectivity with respect to the first and second interlayer dielectric layers 111 and 112. For example, the first and second sacrificial layers 121 and 122 may be formed of silicon nitride, and the first and second interlayer dielectric layers 111 and 112 may be formed of silicon oxide. Each of the first and second sacrificial layers 121 and 122 may have substantially the same thickness, and one of more of the first and second interlayer dielectric layers 111 and 112 may have a thickness that is changed on a partial zone. A lowermost one of the first interlayer dielectric layers 111 may be formed to have a thickness that is relatively large on a zone where the lower semiconductor layer 103 is not formed. For example, the lowermost first interlayer dielectric layer 111 may fill a portion where the lower semiconductor layer 103 is not formed.

A trimming process may be performed on the preliminary stack structure STp including the first and second interlayer dielectric layers 111 and 112 and the first and second sacrificial layers 121 and 122 that are alternately stacked. The trimming process may include forming a mask pattern that partially covers or overlaps a top surface of the preliminary stack structure STp on the cell array region CAR and the contact region CCR, using the mask pattern to pattern the preliminary stack structure STp, reducing an area of the mask pattern, and using the reduced mask pattern to pattern the preliminary stack structure STp. The area reduction of the mask pattern and the using of the mask pattern to pattern the preliminary stack structure STp may be alternately repeatedly performed. The trimming process may outwardly expose at least a portion of each of the first and second interlayer dielectric layers 111 and 112, and the preliminary stack structure STp may have a stepwise structure formed on the contact region CCR. An area of the reduced mask pattern may be adjusted when the trimming process is performed. The adjustment of the reduced mask pattern may cause the first and second interlayer dielectric layers 111 and 112 to have their different lengths in a first direction D1 on top surfaces thereof exposed on the stepwise structure.

A sixth dielectric layer 60 may be formed to cover or overlap the stepwise structure of the preliminary stack structure STp. The sixth dielectric layer 60 may cover or overlap at least a portion of the second substrate 100 and at least a portion of the seventh dielectric layer 80. A top surface of the sixth dielectric layer 60 may be substantially flat, and may be substantially coplanar with that of an uppermost one of the second interlayer dielectric layers 112 included in the preliminary stack structure STp.

First and second through contacts TC1 and TC2 may be formed to penetrate the sixth dielectric layer 60. The first through contact TC1 may further penetrate a portion of the second substrate 100. The formation of the first and second through contacts TC1 and TC2 may include forming holes that penetrate the sixth dielectric layer 60 and have a high aspect ratio, and filling the holes with a conductive material. The first and second through contacts TC1 and TC2 may have their top surfaces substantially coplanar with that of the sixth dielectric layer 60 and that of the uppermost second interlayer dielectric layer 112.

A fifth dielectric layer 53 may be formed to cover or overlap an uppermost surface of the preliminary stack structure STp and the top surface of the sixth dielectric layer 60.

Vertical channel holes CH having a high aspect ratio may be formed to penetrate the fifth dielectric layer 53, the first and second interlayer dielectric layers 111 and 112 and the first and second sacrificial layers 121 and 122 of the preliminary stack structure STp, the lower semiconductor layer 103, and the lower sacrificial layer 101. The vertical channel holes CH may further penetrate a portion of the second substrate 100. The vertical channel holes CH may further penetrate the sixth dielectric layer 60 on the contact region CCR.

The vertical channel holes CH may include first vertical channel holes CH1 that penetrate the first interlayer dielectric layers 111 and the first sacrificial layers 121, and may also include second vertical channel holes CH2 that penetrate the second interlayer dielectric layers 112 and the second sacrificial layers 122. The second vertical channel holes CH2 may overlap in a third direction D3 with the first vertical channel holes CH1, and may be spatially connected to the first vertical channel holes CH1.

First vertical channel structures VS1 may be formed in the vertical channel holes CH on the cell array region CAR. Second vertical channel structures VS2 may be formed in the vertical channel holes CH on the contact region CCR.

The formation of the first and second vertical channel structures VS1 and VS2 may include forming a data storage pattern DSP and a vertical semiconductor pattern VSP that conformally cover or overlap an inner wall of each of the vertical channel holes CH, forming a buried dielectric pattern VI in a space surrounded by the vertical semiconductor pattern VSP, and forming a conductive pad PAD in a space surrounded by the buried dielectric pattern VI and the data storage pattern DSP. The first and second vertical channel structures VS1 and VS2 may have their top surfaces substantially coplanar with that of the fifth dielectric layer 53.

According to some embodiments, the first and second vertical channel structures VS1 and VS2 may not be formed simultaneously. For example, the first vertical channel structures VS1 may be formed on the cell array region CAR, and then the second vertical channel structures VS2 may be formed on the contact region CCR. For example, the vertical channel holes CH may be formed only on the cell array region CAR, and then the first vertical channel structures VS1 may be formed in the vertical channel holes CH. Afterwards, the vertical channel holes CH may be formed on the contact region CCR, and the second vertical channel structures VS2 may be formed in the vertical channel holes CH. In contrast with some of the embodiments discussed above, the second vertical channel structures VS2 may be formed on the contact region CCR, and then the first vertical channel structures VS1 may be formed on the cell array region CAR. In this step, as discussed with reference to FIG. 6A, the second vertical channel structures VS2 may include a material different from that of the first vertical channel structures VS1. This configuration mentioned above may be changed in accordance with design of a three-dimensional semiconductor memory device which is intended to fabricate.

Through structure holes CAPH having a high aspect ratio may be formed to penetrate the fifth dielectric layer 53, the sixth dielectric layer 60, the first interlayer dielectric layers 111 and the first sacrificial layers 121 of the preliminary stack structure STp, the lower semiconductor layer 103, and the lower sacrificial layer 101. In some embodiments, the through structure holes CAPH may further penetrate the second interlayer dielectric layers 112 and the second sacrificial layers 122. The through structure holes CAPH may further penetrate at least a portion of the second substrate 100. The through structure holes CAPH may be formed by a dry etching process. The dry etching process may be performed one time or a plurality of times. When viewed in plan, the through structure holes CAPH may be formed in second pad portions ELp2 which will be discussed below. When viewed in plan, the through structure holes CAPH may be formed in a vertical separation dam structure DAM which will be discussed below.

Through structures CAP may be formed in the through structure holes CAPH. The formation of the through structures CAP may include forming a barrier layer 212 that conformally covers or overlaps an inner wall of each of the through structure holes CAPH, and forming a conductive pattern 214 that fills an unoccupied space of each of the through structure holes CAPH while covering or overlapping an inner wall of the barrier layer 212. The barrier layer 212 and the conductive pattern 214 may be formed by using chemical vapor deposition (CVD) or atomic layer deposition (ALD). The through structures CAP may have their top surfaces substantially coplanar with that of the fifth dielectric layer 53.

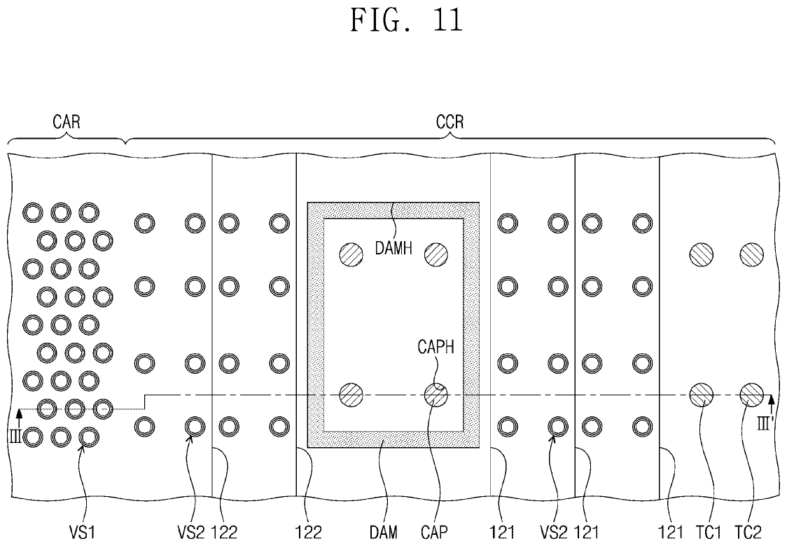

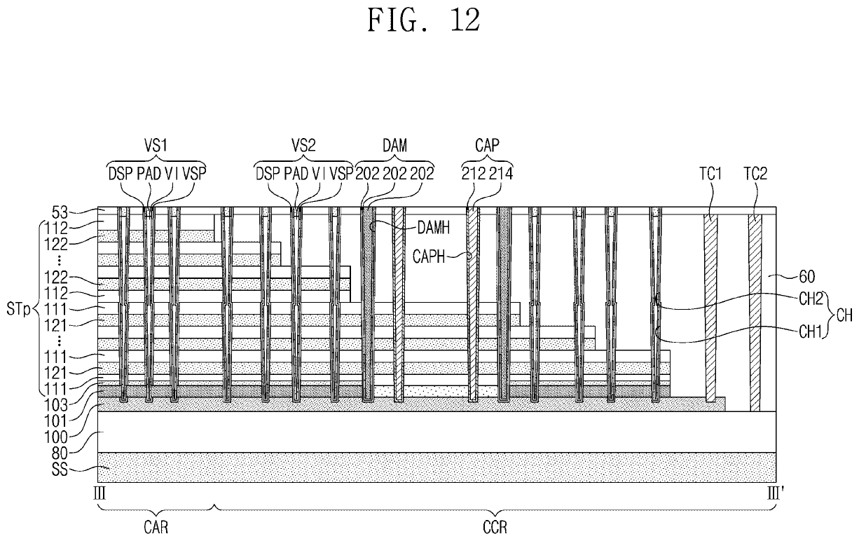

Referring to FIGS. 11 and 12, a vertical separation dam structure trench DAMH having a high aspect ratio may be formed to penetrate the fifth dielectric layer 53, the sixth dielectric layer 60, the first interlayer dielectric layers 111 and the first sacrificial layers 121 of the preliminary stack structure STp, the lower semiconductor layer 103, and the lower sacrificial layer 101. In some embodiments, the vertical separation dam structure trench DAMH may further penetrate the second interlayer dielectric layers 112 and the second sacrificial layers 122. The vertical separation dam structure trench DAMH may further penetrate at least a portion of the second substrate 100. A dry etching process may be used to form the vertical separation dam structure trench DAMH. The dry etching process may be performed one time or a plurality of times. When viewed in plan, the vertical separation dam structure trench DAMH may be formed in second pad portions ELp2 which will be discussed below.

A vertical separation dam structure DAM may be formed in the vertical separation dam structure trench DAMH. The formation of the vertical separation dam structure DAM may include forming a first protection layer 202 that conformally covers or overlaps an inner wall of the vertical separation dam structure trench DAMH, forming a second protection layer 204 that conformally covers or overlaps a sidewall of the first protection layer 202, and forming a buried pattern 206 that fills an unoccupied space of the vertical separation dam structure trench DAMH while covering or overlapping a sidewall of the second protection layer 204. The first protection layer 202, the second protection layer 204, and the buried pattern 206 may be formed by using chemical vapor deposition (CVD) or atomic layer deposition (ALD). The vertical separation dam structure DAM may have a top surface substantially coplanar with that of the fifth dielectric layer 53.

Referring to FIGS. 13, 14A, and 14B, a fourth dielectric layer 52 may be formed to cover or overlap the top surface of the fifth dielectric layer 53, the top surfaces of the first and second vertical channel structures VS1 and VS2, the top surfaces of the through structures CAP, and the top surface of the vertical separation dam structure DAM.

A first trench TR1 may be formed to penetrate the fourth dielectric layer 52, the fifth dielectric layer 53, and the preliminary stack structure STp, and second trenches TR2 may be formed to penetrate the fourth dielectric layer 52, the fifth dielectric layer 53, the preliminary stack structure STp, the lower semiconductor layer 103, and the lower sacrificial layer 101. The second trenches TR2 may further penetrate at least a portion of the second substrate 100. The second trenches TR2 may extend from the cell array region CAR toward the contact region CCR. The first trench TR1 may have a depth less than those of the second trenches TR2. Although not shown, the first trench TR1 may have a bottom surface located at a level higher than that of a top surface of an uppermost one of the first interlayer dielectric layers 111. The second trenches TR2 may have their bottom surfaces located at a level lower than that of a bottom surface of the lower sacrificial layer 101. The bottom surfaces of the second trenches TR2 may be located at a level lower than that of bottom surfaces of the first and second vertical channel structures VS1 and VS2.

The formation of the second trenches TR2 may include forming a mask layer (not shown) on the fourth dielectric layer 52, allowing the mask layer to undergo exposure and development processes to form a trench mask pattern 90, and performing a dry etching process on the trench mask pattern 90.

Referring to FIGS. 15, 16A, and 16B, there may be removed the lower sacrificial layer 101 and the first and second sacrificial layers 121 and 122 exposed by the second trenches TR2. The removal of the lower sacrificial layer 101 and the first and second sacrificial layers 121 and 122 may include performing, for example, a wet etching process that uses hydrofluoric acid (HF) and/or phosphoric acid (H₃PO₄).

When the lower sacrificial layer 101 is removed, there may be also removed a portion of the data storage pattern DSP of each of the first and second vertical channel structures VS1 and VS2 exposed by a space from which the lower sacrificial layer 101 is removed.

A first source conductive pattern SCP1 may be formed to fill the space from which the lower sacrificial layer 101 is removed. The first source conductive pattern SCP1 may be in contact with the vertical semiconductor pattern VSP of each of the first and second vertical channel structures VS1 and VS2. The first source conductive pattern SCP1 may be formed of, for example, an impurity-doped semiconductor material. Although not shown, an air gap may be formed in the first source conductive pattern SCP1. After that, the lower semiconductor layer 103 may be called a second source conductive pattern SCP2, and as a result, a source structure SC may be formed which includes the first and second source conductive patterns SCP1 and SCP2.

The vertical separation dam structure DAM may not be affected by hydrofluoric acid and/or phosphoric acid. Therefore, when viewed in plan, neither the first sacrificial layers 121 nor the lower sacrificial layer 101 may be removed which are disposed in an inner perimeter of the vertical separation dam structure DAM. The first sacrificial layers 121 and the lower sacrificial layer 101 that are not removed may become the first residual sacrificial layers 121a and the residual lower sacrificial layer 101a depicted in FIG. 6A. In some embodiments, when a second stack structure ST2 is provided thereon with second pad portions ELp2 which will be discussed below, the second sacrificial layer 122 disposed in the inner perimeter of the vertical separation dam structure DAM may remain without being removed. Therefore, a mold structure MS may be formed which is surrounded by the vertical separation dam structure DAM.

First and second gate electrodes ELa and ELb may be formed to fill spaces where the first and second sacrificial layers 121 and 122 are removed. The first and second interlayer dielectric layers 111 and 112 may be called first and second interlayer dielectric layers ILDa and ILDb of first and second stack structures ST1 and ST2, and as a result, a stack structure ST may be formed to include the first and second interlayer dielectric layers ILDa and ILDb and the first and second gate electrodes ELa and ELb.

A first separation pattern SP1 may be formed to fill the first trench TR1, and second separation patterns SP2 may be formed to fill the second trenches TR2. The first and second separation patterns SP1 and SP2 may have their top surfaces substantially coplanar with that of the fourth dielectric layer 52.

A third dielectric layer 51 may be formed to cover or overlap the top surface of the fourth dielectric layer 52 and the top surfaces of the first and second separation patterns SP1 and SP2.

On the contact region CCR, cell contacts CC may be formed to penetrate the third, fourth, fifth, and sixth dielectric layers 51, 52, 53, and 60 to come into contact with first pad portions ELp1 of the first and second gate electrodes ELa and ELb. Although not shown, on the contact region CCR, cell contacts CC may be formed to contact the second pad portions ELp2. The cell contacts CC may penetrate at least portions of the first and second interlayer dielectric layers ILDa and ILDb. The cell contacts CC may have top surfaces substantially coplanar with that of the third dielectric layer 51.

On the cell array region CAR, bit-line contact plugs BLCP may be formed to penetrate the third and fourth dielectric layers 51 and 52 to come into contact with the top surfaces of the first vertical channel structures VS1. On the contact region CCR, first and second through contact plugs TCP1 and TCP2 may be formed to penetrate the third, fourth, and fifth dielectric layers 51, 52, and 53 to come into connection with the first and second through contacts TC1 and TC2, respectively. On the contact region CCR, through structure contact plugs CAPCP may be formed to penetrate the third and fourth dielectric layers 51 and 52 to come into contact with the top surfaces of the through structures CAP. A height in the third direction D3 of each of the first and second through contact plugs TCP1 and TCP2 may be greater than a height in the third direction D3 of each of the bit-line contact plugs BLCP and a height in the third direction D3 of each of the through structure contact plugs CAPCP.

Bit lines BL may be formed to contact the bit-line contact plugs BLCP on the third dielectric layer 51 of the cell array region CAR. On the third dielectric layer 51 of the contact region CCR, first conductive lines CL1 may be formed to contact the cell contacts CC and the through structures CAP, and second and third conductive lines CL2 and CL3 may be formed to contact the first and second through contact plugs TCP1 and TCP2, respectively.

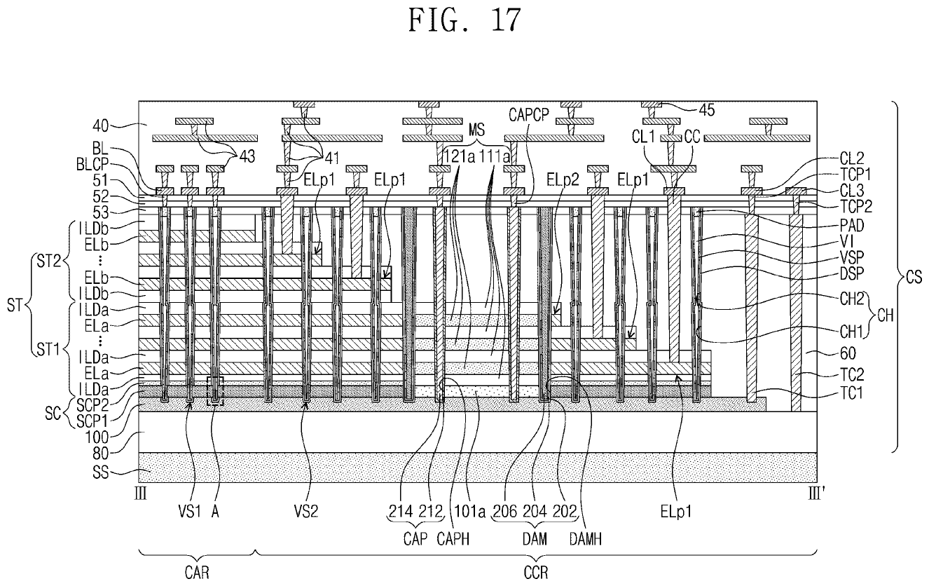

Referring to FIG. 17, bit lines BL may be formed on the third dielectric layer 51, and connection contact plugs 41, connection circuit lines 43, and second bonding pads 450 may be formed to electrically connect to the first, second, and third conductive lines CL1, CL2, and CL3. In addition, a second dielectric layer 40 may be formed to cover or overlap the bit lines BL, the connection contact plugs 41, the connection circuit lines 43, and the second bonding pads 450. The second bonding pads 45 may have their top surfaces substantially coplanar with that of the second dielectric layer 40. Accordingly, the method discussed with reference to FIGS. 9 to 17 may form a cell array structure CS on the sacrificial substrate SS.

Referring back to FIGS. 5, 6A, and 6B together with FIG. 17, the cell array structure CS formed on the sacrificial substrate SS may be bonded to the peripheral circuit structure PS formed on the first substrate 10 by the method discussed with reference to FIG. 8. The sacrificial substrate SS may be provided on the first substrate 10 to allow the cell array structure CS to face the peripheral circuit structure PS. The first bonding pads 35 of the peripheral circuit structure PS and the second bonding pads 45 of the cell array structure CS may be merged while being in contact with each other. After the bonding of the first and second bonding pads 35 and 45, the sacrificial substrate SS may be removed from the cell array structure CS. Thereafter, an input/output pad IOP may be formed. Accordingly, a three-dimensional semiconductor memory device may be fabricated.

According to the present inventive concepts, when viewed in plan, a vertical separation dam structure may be disposed on second pad portions, and a mold structure including a dielectric material may be disposed in an inner perimeter of the vertical separation dam structure. In addition, the mold structure may be penetrated with a pair of through structures that are spaced apart from each other in a first direction or a second direction. For this reason, the pair of through structure may be surrounded by a dielectric material, and thus the pair of through structures and the dielectric material may serve as a capacitor in a cell array structure. Therefore, as there is a reduction in the number of capacitors disposed in a peripheral circuit structure, a three-dimensional semiconductor memory device may increase in integration.

Moreover, as the peripheral circuit structure vertically overlaps the through structures, a reduced electrical connection path may be provided between peripheral transistors and a capacitor electrode. In conclusion, a three-dimensional semiconductor memory device may improve in reliability and electrical properties.

Although the present invention has been described in connection with the some example embodiments of the present inventive concepts illustrated in the accompanying drawings, it will be understood by one of ordinary skill in the art that variations in form and detail may be made therein without departing from the spirit of the present inventive concepts. The above disclosed embodiments should thus be considered illustrative and not restrictive.

What is claimed is:

1. A three-dimensional semiconductor memory device, comprising:
a first substrate comprising a cell array region and a contact region;
a peripheral circuit structure on the first substrate;
a cell array structure on the peripheral circuit structure, wherein the cell array structure comprises a stack structure comprising interlayer dielectric layers and gate electrodes that are alternately stacked on the peripheral circuit structure, a dielectric layer on the stack structure, and a second substrate on the stack structure, wherein the gate electrodes comprise pad portions having a stepwise structure on the contact region;
a vertical separation dam structure that penetrates the dielectric layer and at least a portion of the stack structure, wherein the vertical separation dam structure penetrates at least one of the pad portions;
a mold structure that is adjacent to the vertical separation dam structure, wherein the mold structure comprises a dielectric material; and
through structures that penetrate the dielectric layer and the mold structure.

2. The three-dimensional semiconductor memory device of claim 1,
wherein the mold structure comprises residual interlayer dielectric layers and residual sacrificial layers that are alternately stacked,
wherein the residual interlayer dielectric layers are adjacent to respective ones of the interlayer dielectric layers opposite the vertical separation dam structure, and
wherein the residual sacrificial layers are adjacent respective ones of the gate electrodes opposite the vertical separation dam structure.

3. The three-dimensional semiconductor memory device of claim 2,
wherein the residual interlayer dielectric layers comprise silicon oxide, and
wherein the residual sacrificial layers comprise silicon nitride.

4. The three-dimensional semiconductor memory device of claim 1,
wherein the through structures penetrate a portion of the second substrate, and
wherein a top surface of each of the through structures is in contact with the second substrate.

5. The three-dimensional semiconductor memory device of claim 1, further comprising:
a residual lower sacrificial layer between the mold structure and the second substrate,
wherein the residual lower sacrificial layer is in contact with the vertical separation dam structure, and
wherein the through structures penetrate the residual lower sacrificial layer.

6. The three-dimensional semiconductor memory device of claim 1,
wherein each of the through structures is in a respective through structure hole,
wherein ones of the through structures comprise:
a barrier layer that conformally overlaps an inner sidewall and a bottom surface of the respective through structure hole; and
a conductive pattern in an inner space of the respective through structure hole, the inner space being surrounded by the barrier layer in a plan view,
wherein the barrier layer comprises at least one of titanium nitride or tantalum nitride, and
wherein the conductive pattern comprises at least one of a doped semiconductor, a metal, or a transition metal.

7. The three-dimensional semiconductor memory device of claim 1, further comprising:
vertical channel structures that penetrate the stack structure and have top surfaces in contact with the second substrate,
wherein bottom surfaces of the through structures are coplanar with bottom surfaces of the vertical channel structures.

8. The three-dimensional semiconductor memory device of claim 1,
wherein the cell array structure further comprises conductive lines, connection contact plugs, and connection circuit lines between the peripheral circuit structure and the stack structure, and
wherein the through structures are electrically connected to the peripheral circuit structure through the conductive lines, the connection contact plugs, and/or the connection circuit lines.

9. The three-dimensional semiconductor memory device of claim 1,
wherein the vertical separation dam structure is in a vertical separation dam structure trench,
wherein the vertical separation dam structure comprises:
a first protection layer that conformally is on an inner sidewall and a bottom surface of the vertical separation dam structure trench;
a second protection layer that overlaps an inner sidewall of the first protection layer; and
a buried pattern in an inner space of the vertical separation dam structure trench, wherein the inner space is surrounded by the second protection layer in a plan view,
wherein the first protection layer comprises a silicon oxide layer or a silicon oxynitride layer,
wherein the second protection layer comprises a silicon nitride layer, and
wherein the buried pattern comprises an impurity-doped semiconductor material, an impurity-undoped intrinsic semiconductor material, or a polycrystalline semiconductor material.

10. The three-dimensional semiconductor memory device of claim 1, wherein a top surface of the vertical separation dam structure is in contact with the second substrate.

11. The three-dimensional semiconductor memory device of claim 1, wherein a bottom surface of each of the through structures and a bottom surface of the vertical separation dam structure are coplanar with each other.

12. The three-dimensional semiconductor memory device of claim 1, wherein the vertical separation dam structure has a polygonal or circular annular shape when viewed in plan.

13. The three-dimensional semiconductor memory device of claim 1, wherein an outer sidewall of the mold structure is in contact with an inner sidewall of the vertical separation dam structure.

14. A three-dimensional semiconductor memory device, comprising:
a first substrate comprising a cell array region and a contact region;
a peripheral circuit structure on the first substrate;
a cell array structure on the peripheral circuit structure, wherein the cell array structure comprises interlayer dielectric layers and gate electrodes that are alternately stacked in a stack structure, a dielectric layer on the stack structure, and a second substrate on the stack structure;
a mold structure that penetrates the stack structure and comprises a dielectric material; and
a first through structure and a second through structure that penetrate the mold structure and are spaced apart from each other.

15. The three-dimensional semiconductor memory device of claim 14,
wherein the gate electrodes comprise pad portions on the contact region, the pad portions having a stepwise structure along a first direction parallel to a top surface of the first substrate,
wherein the pad portions comprise first pad portions and a second pad portion between the first pad portions,
wherein a length in the first direction of the second pad portion is greater than a length in the first direction of each of the first pad portions, and
wherein the mold structure is in the second pad portion, in a plan view.

16. The three-dimensional semiconductor memory device of claim 15, further comprising:
a vertical separation dam structure that is in the second pad portion and surrounds the mold structure, in the plan view,
wherein the vertical separation dam structure is in a vertical separation dam structure trench,
wherein the vertical separation dam structure comprises:
a first protection layer that is on an inner sidewall and a bottom surface of the vertical separation dam structure trench;
a second protection layer that is on an inner sidewall of the first protection layer; and
a buried pattern in an inner space of the vertical separation dam structure trench,
wherein the inner space is surrounded by the second protection layer in the plan view,
wherein the first protection layer comprises a silicon oxide layer or a silicon oxynitride layer,
wherein the second protection layer comprises a silicon nitride layer, and
wherein the buried pattern comprises an impurity-doped semiconductor material, an impurity-undoped intrinsic semiconductor material, or a polycrystalline semiconductor material.

17. The three-dimensional semiconductor memory device of claim 14,
wherein each of the first and second through structures comprises a barrier layer and a conductive pattern on an inner sidewall of the barrier layer,
wherein the barrier layer comprises at least one of titanium nitride or tantalum nitride,
wherein the conductive pattern comprises at least one of a doped semiconductor, a metal, or a transition metal, and
wherein a top surface of the second through structure is in contact with the second substrate.

18. The three-dimensional semiconductor memory device of claim 17,
wherein the cell array structure further comprises conductive lines, connection contact plugs, and connection circuit lines between the peripheral circuit structure and the stack structure, and
wherein the first and second through structures are electrically connected to the peripheral circuit structure through the conductive lines, the connection contact plugs, and/or the connection circuit lines.

19. An electronic system, comprising:
a three-dimensional semiconductor memory device comprising a first substrate that comprises a cell array region and a contact region, a peripheral circuit structure on the first substrate, a cell array structure on the peripheral circuit structure, a through contact that penetrates the cell array structure, and an input/output pad on the through contact; and
a controller configured to electrically connect the input/output pad with the three-dimensional semiconductor memory device and configured to control the three-dimensional semiconductor memory device,
wherein the cell array structure comprises:
interlayer dielectric layers and gate electrodes that are alternately stacked in a stack structure on the peripheral circuit structure;
a second substrate on the stack structure; and
a vertical separation dam structure and a capacitor that penetrate the stack structure,
wherein the gate electrodes comprise pad portions having a stepwise structure on the contact region,
wherein the capacitor comprises a first through structure and a second through structure that are spaced apart from each other,
wherein the vertical separation dam structure is in one of the pad portions in a plan view, and
wherein the first and second through structures are surrounded by the vertical separation dam structure in the plan view.

20. The electronic system of claim 19,
wherein the peripheral circuit structure comprises peripheral transistors on the first substrate and first bonding pads connected to the peripheral transistors,
wherein the cell array structure further comprises:
a dielectric layer on the stack structure;
cell contacts that penetrate the dielectric layer and contact the gate electrodes of the stack structure;
vertical channel structures that penetrate the stack structure and contact the second substrate;
conductive lines electrically connected to the cell contacts and the first and second through structures;
bit lines connected to the vertical channel structures; and
second bonding pads connected to the bit lines and the conductive lines, and
wherein the first bonding pad and the second bonding pad are bonded into a single unitary body.
